(19) United States
(12) Patent Application Publication
(10) Pub. No.: US 2016/0108282 A1
(43) Pub. Date: Apr. 21, 2016

(54) GAS BARRIER FILM AND METHOD FOR PRODUCING THE SAME

(71) Applicant: KONICA MINOLTA, INC., Tokyo (JP)

(72) Inventor: Hirohide ITO, Tokyo (JP)

(21) Appl. No.: 14/893,824

(22) PCT Filed: May 26, 2014
(86) PCT No.: PCT/JP2014/063871

§ 371 Date: Nov. 24, 2015

(30) Foreign Application Priority Data
May 28, 2013 (JP) 2013-112138

(51) Int. Cl. C09D 183/14; C23C 16/48; C09D 183/06; C23C 16/22

(52) U.S. Cl. CPC C09D 183/14; C23C 16/22; C23C 16/48; C09D 183/06

(57) ABSTRACT

[Object] To provide a means capable of further improving gas barrier capabilities and durability of gas barrier capabilities for a gas barrier film.

[Solving Means] A gas barrier film having: a substrate; a first barrier layer that is arranged on at least one surface of the substrate, has a film density of 1.5 to 2.1 g/cm³, and includes an inorganic compound; and a second barrier layer that is formed on the surface of the substrate on the same side where the first barrier layer is formed and includes silicon atoms, oxygen atoms, and at least one added element selected from the group consisting of elements of Groups 2-14 of the long form of the periodic table (excluding silicon and carbon), the abundance ratio of oxygen atoms to silicon atoms (O/Si) being 1.4 to 2.2, and the abundance ratio of nitrogen atoms to silicon atoms (N/Si) being 0 to 0.4.

### TECHNICAL FIELD

The present invention relates to a gas barrier film and a method for producing the same, and more particularly, to a gas barrier film that is used for electronic devices such as an organic electroluminescence (EL) device, a solar cell device, or a liquid crystal display.

### BACKGROUND ART

Conventionally, a gas barrier film having a relatively simple structure, in which inorganic films such as vapor deposition films of metals or metal oxide are provided on the surface of a resin substrate, is being used in order to prevent the penetration of gas such as vapor or oxygen in the fields of food, packaging materials, medicine and medical supplies, and the like.

In recent years, such a gas barrier film that prevents the penetration of vapor or oxygen is being used for the fields of electronic devices such as a liquid crystal display (LCD) device, a solar cell (PV), and an organic electroluminescence (EL). In order to impart flexibility, and light and unbreakable properties to these electronic devices, a gas barrier film having high gas barrier properties is required rather than a hard and easily breakable glass substrate.

Away for obtaining a gas barrier film capable of being applied for an electronic device is roughly classified into a dry coating method for depositing a gas barrier layer on a substrate with a vacuum film-forming way such as vapor deposition•sputtering•CVD and a wet coating method for forming a gas barrier layer on a substrate by applying a coating solution under a normal pressure on the substrate and performing a drying•conversion treatment (for both of the drycoating method and wetcoating method, refer to IEEE JOURNAL OF SELECTED TOPICS IN QUANTUM ELECTRONICS, Vol 10, 45-57 (2004)).

Meanwhile, as the more preferred method of a wet coating method, a sol-gel method using metal alkoxides is known as disclosed in the specification of U.S. Pat. No. 6,503,634. In addition, as other preferred method of a wet coating method, there is known a method for applying a metal oxide precursor and converting it as disclosed in L. Prager et al., Chem. Eur. J. 2007, 13, 8522.

Here, the dry coating method requires a vacuum process, and especially, in order to produce a high barrier film that is required for an electronic device having WVTR=1×10⁻³ g/m²·day (40° C. and 90% RH) or less, there is a problem of low productivity. In addition, a thin-film formed by such a method is characterized in that, since the impurities present on a surface influence and the growing of the thin-film is formed through an island-shaped structure, the barrier properties were reduced by the defects derived in the bounded parts between islands and by being these defects to be the passage of water.

Meanwhile, according to the wet coating method, it is expected that it is possible to obtain the production form such as a roll-to-roll and to produce a high barrier film with high productivity. In addition, according to the wet coating method, it is expected that the defects caused in the growing of a thin film are low, but for the wet coating method, the applicable barrier layer precursor is applied, and then, the conversion treatment of the coating film thus obtained is performed by heat, light, oxygen, water, and the like to form a barrier layer. For this reason, during the conversion treatment, there were problems in that the materials were unnecessarily radiated, and it was easy to produce defects or deformations by the conversion of coating film. Especially, the barrier layer formed according to the wet coating method is characterized that the densification of the barrier layer is insufficient, and the density of film is small as compared with the barrier layer manufactured by the dry coating method.

### SUMMARY OF INVENTION

As described above, there is an expectation for high productivity of the barrier layer manufactured by the wet coating method, but there are problems in that the barrier properties are insufficient or are easily reduced by the bending or elongation of a substrate. Therefore, the solutions therefor are required.

The present invention was made in view of the above-described circumstances, and an object of the present invention is to provide a means for further improving gas barrier capabilities and durability of gas barrier capabilities for a gas barrier film.

The present inventors conducted intensive studies to solve the above-described problems. As a result, the present inventors found that the above-described problems can be solved by the gas barrier film, in which a barrier layer (first barrier layer) having a predetermined film density (specifically, 1.5 to 2.1 g/cm³) and including an inorganic compound and a barrier layer (second barrier layer) including a predetermined added element along with silicon atoms and oxygen atoms, in which the abundance ratios of oxygen atoms and nitrogen atoms to the silicon atoms are respectively controlled to be the values in the predetermined range, are arranged on the surface of the same side of a substrate. Accordingly, the present inventors completed the present invention.

In other words, according to an aspect of the present invention, there is provided a gas barrier film having: a substrate; a first barrier layer that is arranged on at least one surface of the substrate, has a film density of 1.5 to 2.1 g/cm³, and includes an inorganic compound; and a second barrier layer that is formed on the surface of the substrate on the same side where the first barrier layer is formed and includes silicon atoms, oxygen atoms, and at least one added element selected from the group consisting of elements of Groups 2-14 of the long form of the periodic table (excluding silicon and carbon), the abundance ratio of oxygen atoms to silicon atoms (O/Si) being 1.4 to 2.2, and the abundance ratio of nitrogen atoms to silicon atoms (N/Si) being 0 to 0.4.

In addition, according to another aspect of the present invention, there is provided a method for producing the gas barrier film according to the above aspect, in which the method includes forming the first barrier layer by applying a first coating solution including an inorganic compound or a precursor thereof on at least one surface of the substrate to form a first coating film, and performing the conversion treatment of the first coating film.

### DESCRIPTION OF EMBODIMENTS

An aspect of the present invention relates to a gas barrier film having: a substrate; a first barrier layer that is arranged on at least one surface of the substrate, has a film density of 1.5 to 2.1 g/cm³, and includes an inorganic compound; and a second barrier layer that is formed on the surface of the substrate on the same side where the first barrier layer is formed and includes silicon atoms, oxygen atoms, and at least one added element selected from the group consisting of elements of Groups 2-14 of the long form of the periodic table (excluding silicon and carbon), the abundance ratio of oxygen atoms to silicon atoms (O/Si) being 1.4 to 2.2, and the abundance ratio of nitrogen atoms to silicon atoms (N/Si) being 0 to 0.4.

By having such a configuration, there is provided a means capable of further improving gas barrier capabilities and durability of gas barrier capabilities for the gas barrier film.

The detailed reason why the gas barrier film according to the present aspect has excellent gas barrier capabilities and durability of gas barrier capabilities is not clear. However, it is considered that this is because of the following reasons.

For example, the gas barrier layer (barrier layer) that is formed with a wet coating method is generally formed by applying an applicable barrier layer precursor, performing the evaporation of a solvent, or the condensation crosslinking reaction of the barrier layer precursor, and then, performing the conversion treatment to make a coating film dense. However, the barrier layer formed by such a method is characterized in that low film density is exhibited as compared with the original value of a material because the structure of a coating film at the time of releasing a solvent or an initial time is maintained, and thus, the conversion treatment is not complete. In addition, there are also characterized in that when the coating film becomes dense and is converted into a barrier layer, the large structure change is physically and chemically involved, but the densification of barrier layer is not uniformly performed, and thus, the deformation occurs in the barrier layer.

As described above, it is presumed that in the low film density of the barrier layer formed by a wet coating method or the barrier layer formed by a dry process, cracks are generated at the time of production or new cracks are generated by the bending and expansion of a substrate, which are caused by the deformation or un-uniformity present in the barrier layer, so as to exhibit insufficient barrier capabilities or durability thereof. In contrast, according to the gas barrier film of the present aspect, it is considered that, even when the film density of the first barrier layer is relatively low, the above-described deformation of the barrier layer is moderated since the second barrier layer having the predetermined compositions is present together, and as a result, the generation of cracks is suppressed, thereby promoting the improvements of gas barrier capabilities and durability thereof. However, when the dense property of the first barrier layer is significantly low, the effect of the present invention is not exhibited. Therefore, it is presumed that the density of the first barrier layer should be the value within the specific range.

In addition, the above-described mechanism is based on presumption, and the present invention is not limited to the above-described mechanism.

Hereinafter, the preferred embodiments of the present invention will be described. In addition, the present invention is not limited to the following embodiments.

In addition, in the present specification, “X to Y” that represents the range means “X or more and Y or less”. In addition, unless otherwise specified, operations and physical properties are measured under the conditions of a room temperature (20 to 25° C.) and relative humidity of 40 to 50%.

<Gas Barrier Film>

The gas barrier film according to one aspect of the present invention has a substrate, a first barrier layer, and a second barrier layer. As long as the first barrier layer and the second barrier layer are arranged on the same side of the substrate, their order is irrelevant. In other words, it may be the arrangement of a substrate/first barrier layer/second barrier layer, or the arrangement of a substrate/second barrier layer/first barrier layer. From the viewpoint that the effect of the present invention is magnificently exhibited, the arrangement of a substrate/first barrier layer/second barrier layer (having the constitution of having a substrate, a first barrier layer, and a second barrier layer in order) is preferred. For this reason, hereinafter, based on the arrangement of a substrate/first barrier layer/second barrier layer, the explanation will be presented. In addition, the first barrier layer and the second barrier layer may be each independently arranged in one layer or two or more layers. Here, when the total number of the first barrier layer and the second barrier layer is three layers or more, the constitution, in which the barrier layer that is the closest layer to the substrate is the first barrier layer, and the barrier layer that is the farthermost layer from the substrate is the second barrier layer, is preferred. By being such a constitution, it is possible to provide a gas barrier film having excellent durability as well as gas barrier properties at an initial time.

The gas barrier film of the present invention may further include other members. The gas barrier film of the present invention may include other members, for example, between a substrate and a first barrier layer, between a first barrier layer and a second barrier layer, on a second barrier layer, or other surface of a substrate without a first barrier layer and a second barrier layer. Here, other members are not particularly limited, and the same members as the members that are used for a conventional gas barrier film may be used or the members that are used for a conventional gas barrier film may be properly modified and then used. In detail, there may be a barrier layer that does not satisfy the regulations of the above-described first barrier layer and the second barrier layer, an intermediate layer, a protective layer, a smoothing layer, an anchor coat layer, a bleed-out prevention layer, a functionalized layer such as a desiccant layer having moisture absorbability or an antistatic preventing layer, and the like.

A gas barrier unit having the first barrier layer and the second barrier layer may be formed on the surface of one side of a substrate or may be formed on the surfaces of both sides of a substrate. In addition, the gas barrier unit may include a layer without gas barrier properties. In addition, in the present specification, “a barrier layer” means the layer having the water vapor transmission rate (WVTR) of less than 1×10⁻² g/(m²·day) at 40° C. and 90%, and the layer having the WVTR that exceeds 1×10⁻² g/(m²·day) is not included in the concept of “a barrier layer”.

As the gas barrier properties of the gas barrier film of the present invention, the water vapor transmission rate (WVTR) at 40° C. and 90% is preferably 1×10⁻³ g/(m²·day) or less, preferably 1×10⁻⁴ g/(m²·day) or less, and particularly preferably 1×10⁻⁵ g/(m²·day) or less.

[Substrate]

As a substrate for the gas barrier film according to the present invention, a plastic film or plastic sheet is preferably used, and the film or sheet that is constituted of a colorless and transparent resin is more preferably used. A material, thickness, and the like of the plastic film to be used are not particularly limited, as long as they can retain a first barrier layer, a second barrier layer, and the like. Depending on the use objects, the films may be properly selected. As the plastic film, in detail, there may be a thermoplastic resin such as a polyester resin, a methacrylic resin, a methacrylic acid-maleic acid copolymer, a polystyrene resin, a transparent fluororesin, polyimide, a fluorinated polyimide resin, a polyamide resin, a polyamide imide resin, a polyetherimide resin, a cellulose acylate resin, a polyurethane resin, a polyetheretherketone resin, a polycarbonate resin, an alicyclic polyolefin resin, a polyarylate resin, a polyether sulfone resin, a polysulfone resin, a cycloolefin copolymer, a fluorene ring-modified polycarbonate resin, an alicyclic-modified polycarbonate resin, a fluorene ring-modified polyester resin, and an acryloyl compound.

When the gas barrier film according to the present invention is used as a substrate of an electronic device such as an organic EL device, the substrate is preferably constituted of a material having heat resistance. In detail, the substrate having the linear expansion coefficient of 1 ppm/K or more and 100 ppm/K or less, and also, the glass transition temperature (Tg) of 100° C. or higher and 500° C. or lower is used. The Tg or linear expansion coefficient of the substrate may be adjusted by adding an additive. The more preferred specific examples of the thermoplastic resin capable of being used as a substrate may include, for example, polyethylene terephthalate (PET: 70° C.), polyethylene naphthalate (PEN: 120° C.), polycarbonate (PC: 140° C.), alicyclic polyolefine (for example, ZEONOR (Registered Trademark) 1600 manufactured by Zeon Corp.: 160° C.), polyarylate (PAr: 210° C.), polyether sulfone (PES: 220° C.), polysulfone (PSF: 190° C.), cycloolefin copolymer (COC: compound disclosed in JP 2001-150584 A: 162° C.), polyimide (for example, NEOPULIM (Registered Trademark) manufactured by Mitsubishi Gas Chemical Company, Inc.: 260° C.), fluorene ring-modified polycarbonate (BCF-PC: compound disclosed in JP 2000-227603 A: 225° C.), alicyclic-modified polycarbonate (IP-PC: compound disclosed in JP 2000-227603 A: 205° C.), an acryloyl compound (compound disclosed in JP 2002-80616 A: 300° C. or higher), and the like (temperatures in parenthesis exhibit Tg).

When the gas barrier film according to the present invention is combined with a polarization plate, for example, and then used, it is preferable to arrange the barrier layer of the gas barrier film to face the inner side of a cell. More preferably, the barrier layer of the gas barrier film is arranged at the innermost side (adjacent to a device) of a cell. At this time, since the gas barrier film is arranged at the inner side of a cell than a polarization plate, the retardation value of the gas barrier film is important. As the used type of the gas barrier film with such an embodiment, it is preferable that the gas barrier film using a substrate film having the retardation value of 10 nm or less and a circular polarization plate (¼ wavelength plate+(½ wavelength plate)+linear polarization plate) are laminated, and then used; or the gas barrier film using a substrate film having the retardation value of 100 nm to 180 nm, which is capable of being used as ¼ wavelength plate, is combined with a linear polarization plate, and then used.

Since the gas barrier film according to the present invention is used as an electronic device such as an organic EL device, a substrate is preferably transparent. In other words, the light transmittance is generally 80% or more, preferably 85% or more, and more preferably 90% or more. The light transmittance may be calculated by measuring the total light transmittance and the scattered light quantity using a method disclosed in JIS K7105: 1981, that is, an integrating sphere-typed light transmittance-measuring device, and then, subtracting the diffuse transmittance from the total light transmittance.

The thickness of the substrate that is used for the gas barrier film according to the present invention may be properly selected in accordance with the intended application, and thus, is not particularly limited. However, the thickness thereof is typically 1 to 800 μm, and preferably 10 to 200 μm. These plastic films may include functional layers such as a transparent conductive layer, a primer layer, and a clear hard coating layer. In addition to the above-described layers, as the functional layers, the layers disclosed in paragraphs Nos. [0036] to [0038] of JP 2006-289627 A may be preferably employed.

The substrate having high surface smoothness is preferred. For the surface smoothness, the average surface roughness (Ra) is preferably 2 nm or less. The lower limit thereof is not particularly limited, but practically, 0.01 nm or more. If necessary, both sides of a substrate or the side having at least a barrier layer may be polished so as to improve smoothness.

In addition, the above-exemplified substrates may be an un-stretched film or a stretched film.

For at least the side having the first barrier layer of the substrate according to the present invention, the known various treatments for improving adhesion, for example, a corona discharge treatment, a flame treatment, an oxidation treatment, a plasma treatment, the lamination of the smoothing layer to be described below, or the like may be performed, or if necessary, the combination of these treatments may be preferably performed.

[First Barrier Layer]

The first barrier layer has the film density of 1.5 to 2.1 g/cm³, and includes an inorganic compound.

The method for measuring the film density in the present invention is not particularly limited as long as it can measure the film density. In detail, there are known a method for calculating the film density from the film thicknesses obtained from the method using an electron microscope, and the difference between the weights before and after forming a barrier layer; a method for obtaining the film density from the difference between the weights before and after etching and the film thicknesses after etching with an aqueous solution of fluorinated acid; a method for optimizing simulation parameter by comparing the profile obtained by performing the incidence of X-ray on the surface of a sample in the ultra-low angle using an XRR (X-ray reflectance method) and then by measuring the profile of X-ray intensity reflected in the incident angle in the mirror plane direction with the simulation result; and the like. In the present invention, the film density of the first barrier layer is necessarily 1.5 to 2.1 g/cm³ as the value for generating various problems caused by the relatively small film density, preferably 1.7 to 2.1 g/cm³, and more preferably 1.9 to 2.1 g/cm³.

The inorganic compound included in the first barrier layer is not particularly limited, but examples thereof may include metal oxides, metal nitrides, metal carbides, metal oxynitrides, or metal oxycarbides. Among them, from the viewpoint of gas barrier capabilities, oxides, nitrides, carbides, oxynitrides, or oxycarbides, which include one or more metals selected from Si, Al, In, Sn, Zn, Ti, Cu, Ce, and Ta, may be preferably used; oxides, nitrides, or oxynitrides of the metal selected from Si, Al, In, Sn, Zn, and Ti are more preferred; and especially, oxides, nitrides, or oxynitrides of at least one type of Si and Al are preferred. As suitable inorganic compounds, in detail, there may be complexes such as silicon oxide, silicon nitride, silicon oxynitride, silicon carbide, silicon oxycarbide, aluminum oxide, titanium oxide, or aluminum silicate. It may include other elements as an additional component.

The content of the inorganic compound included in the first barrier layer is not particularly limited, but in the first barrier layer, preferably 50% by weight or more, more preferably 80% by weight or more, still more preferably 95% by weight or more, particularly preferably 98% by weight or more, and most preferably 100% by weight (that is, the first barrier layer is made of an inorganic compound).

The first barrier layer includes an inorganic compound and thus has gas barrier properties. Here, when calculating in the laminate with the first barrier layer formed on a substrate, for the gas barrier properties of the first barrier layer, the water vapor transmission rate (WVTR) is preferably 5 g/(m²·day) or less, more preferably 0.1 g/(m²·day) or less, and still more preferably 0.01 g/(m²·day) or less, at 40° C. and 90%.

<Formation of First Barrier Layer; Wet Coating Method (Applying Method)>

A typical way for forming a first barrier layer according to the present invention is a wet coating method (applying method). However, if there is the condition for obtaining a barrier layer having a relatively small film density as described above, the first barrier layer may be formed by a dry process. In detail, for example, the barrier layer formed by a wet coating method is formed by applying a solution including an inorganic compound or a precursor thereof (in the present specification, also called “a first coating solution”) on at least one surface of the above-described substrate, and then, by performing the conversion treatment of the coating film thus obtained (in the present specification, also called “a first coating film”). In the present specification, a method of forming a coating film by applying a solution (coating solution) may be referred to as “a wet coating method” or “an applying method”, which are all synonymous. According to the review of the present inventors, it is determined that the barrier layer (gas barrier layer) formed by performing the conversion treatment of the coating film obtained by a wet coating method (applying method) has the film density that does not exceed 2.1.

For the details of “an applying method” for forming the first barrier layer according to the present invention, when using the compound including silicon as an inorganic compound, which is included in the first barrier layer (a preferred embodiment of the present invention), the case of using a coating solution including a silicon compound as the precursor of an inorganic compound in the applying method will be described below as an example. In addition, as a preferred embodiment of the way for forming a first barrier layer, there maybe a sol-gel method using a silicon compound to be described below or a way for forming a first barrier layer through the conversion of polysilazane or polysiloxane (as the precursor of an inorganic compound). The way for forming a first barrier layer through the conversion of polysilazane or polysiloxane is more preferred, and from the viewpoint of excellent barrier capabilities, the way for forming a first barrier layer through the conversion of polysilazane is most preferred.

(Silicon Compound)

The silicon compound as the precursor of an inorganic compound included in the first barrier layer is not particularly limited as long as it can prepare the coating solution including a silicon compound.

In detail, examples thereof may include perhydropolysilazane, organopolysilazanes, silsesquioxanes, tetramethylsilane, trimethylmethoxysilane, dimethyldimethoxysilane, methyltrimethoxysilane, trimethylethoxysilane, dimethyldiethoxysilane, methyltriethoxysilane, tetramethoxysilane, tetramethoxysilane, hexamethyldisiloxane, hexamethyldisilazane, 1,1-dimethyl-1-silacyclobutane, trimethylvinylsilane, methoxydimethylvinylsilane, trimethoxyvinylsilane, ethyltrimethoxysilane, dimethyldivinylsilane, dimethylethoxyethynylsilane, diacetoxydimethylsilane, dimethoxymethyl-3,3,3-trifluoropropylsilane, 3,3,3-trifluoropropyltrimethoxysilane, aryltrimethoxysilane, ethoxydimethylvinylsilane, arylaminotrimethoxysilane, N-methyl-N-trimethylsilylacetamide, 3-aminopropyltrimethoxysilane, methyltrivinylsilane, diacetoxymethylvinylsilane, methyltriacetoxysilane, aryloxydimethylvinylsilane, diethylvinylsilane, butyltrimethoxysilane, 3-aminopropyldimethylethoxysilane, tetravinylsilane, triacetoxyvinylsilane, tetraacetoxysilane, 3-trifluoroacetoxypropyltrimethoxysilane, diaryldimethoxysilane, butyldimethoxyvinylsilane, trimethyl-3-vinylthiopropylsilane, phenyltrimethylsilane, dimethoxymethylphenylsilane, phenyltrimethoxysilane, 3-acryloxypropyldimethoxymethylsilane, 3-acryloxypropyltrimethoxysilane, dimethylisopentyloxyvinylsilane, 2-aryloxyethylthiomethoxytrimethylsilane, 3-glycidoxypropyltrimethoxysilane, 3-arylaminopropyltrimethoxysilane, hexyltrimethoxysilane, heptadecafluorodecyltrimethoxysilane, dimethylethoxyphenylsilane, benzoyloxytrimethylsilane, 3-methacryloxypropyldimethoxymethylsilane, 3-methacryloxypropyltrimethoxy silane, 3-isocyanatepropyltriethoxysilane, dimethylethoxy-3-glycidoxypropylsilane, dibutoxydimethylsilane, 3-butylamino-propyltrimethylsilane, 3-dimethyl-aminopropyldiethoxymethylsilane, 2-(2-aminoethylthioethyl)triethoxysilane, bis(butylamino)dimethylsilane, di-vinylmethylphenylsilane, diacetoxymethylphenylsilane, dimethyl-p-tolylvinylsilane, p-styryltrimethoxysilane, diethylmethylphenylsilane, benzyldimethylethoxysilane, diethoxymethylphenylsilane, decylmethyldimethoxysilane, diethoxy-3-glycidoxypropylmethylsilane, octyloxytrimethylsilane, phenyltrivinylsilane, tetraaryloxysilane, dodecyltrimethylsilane, diarylmethylphenylsilane, diphenylmethylvinylsilane, diphenylethoxymethylsilane, diacetoxydiphenylsilane, dibenzyldimethylsilane, diaryldiphenylsilane, octadecyltrimethylsilane, methyloctadecyldimethylsilane, dococylmethyldimethylsilane, 1,3-divinyl-1,1,3,3-tetramethyldisiloxane, 1,3-divinyl-1,1,3,3-tetramethyldisilazane, 1,4-bis(dimethylvinylsilyl)benzene, 1,3-bis(3-acetoxypropyl)tetramethyldisiloxane, 1,3,5-trimethyl-1,3,5-trivinylcyclotrisiloxane, 1,3,5-tris(3,3,3-trifluoropropyl)-1,3,5-trimethylcyclotrisiloxane, octamethylcyclotetrasiloxane, 1,3,5,7-tetraethoxy-1,3,5,7-tetramethylcyclotetrasiloxan e, decamethylcyclopentasiloxane, and the like. These silicon compounds may be used singly or in combination of two or more types thereof.

Examples of the silsesquioxane may include, as Q8 series manufactured by Mayaterials, Inc., Octakis tetramethylammonium)pentacyclo-octasiloxane-octakis(yloxide)hydrate; Octa(tetramethylammonium)silsesquioxane, Octakis(dimethylsiloxy)octasilsesquioxane, Octa[[3-[(3-ethyl-3-oxetanyl)methoxy]propyl]dimethylsiloxy]octasilsesquioxane; Octaallyloxetane silsesquioxane, Octa[(3-Propylglycidylether)dimethylsiloxy]silsesquioxane; Octakis[[3-(2,3-epoxypropoxy)propyl]dimethylsiloxy]octasilsesquioxane, Octakis[[2-(3,4-epoxycyclohexyl)ethyl]dimethylsiloxy]octasilsesquioxane, Octakis[2-(vinyl)dimethylsiloxy]silsesquioxane; Octakis(dimethylvinylsiloxy)octasilsesquioxane, Octakis[(3-hydroxypropyl)dimethylsiloxy]octasilsesquioxane, Octa[(methacryloylpropyl)dimethylsilyloxy]silsesquioxane, Octakis[(3-methacryloxypropyl)dimethylsiloxy]octasilsesq uioxane, hydrogenated silsesquioxane without an organic group, and the like.

Furthermore, as described in the specification of U.S. Pat. No. 6,503,634, a material made of an inorganic-organic hybrid polymer based on a Si—O—Si-network is preferably used. As a preferred example thereof, there is ORMOCER (Registered Trademark). ORMOCER is developed for a silicate research in Fraunhofer Institute. They are defined as hydrolysis condensate of organic polysiloxane or a (semi-) metal compound, especially, a silicon compound, and are modified (deformed) by an organic group (an organically polymerizable/polymerized or unpolymerizable group) bound with a (semi-) metal atom. In addition to the silicon compound, it may be possible to be other hydrolysable/hydrolyzed metal compounds (for example, aluminum, boron, germanium, and the like).

The production and properties of organically modified polysiloxane or (hetero-) silicic acid polycondensates (often, also called “silane resin”) are disclosed in many publications. Here, instead of them, for example, Hybrid Organic-Inorganic Materials, MRS Bulletin 26(5), 364 ff (2001) is referred to. In general, such a material is generally produced by using a so-called sol-gel method. For this production, a hydrolysis-sensitive monomer or pre-condensed silane is subjected to the hydrolysis or condensation in the presence of newly co-condensable materials, for example, alkoxide of boron, germanium, zirconium, or titanium in some cases, and in some cases, additive compounds that can act as a network accelerator or a modifier, or other additives, for example, dyes, and filler materials. The semi-metal or metal-cation (M) of copolymerizable material is added in a Si—O—Si-backbone as a hetero atom, and thus, it is possible to generate the bonds of Si—O-M- and M-O-M-.

Among them, from the viewpoint of film-forming properties, few defects such as cracks, and small amount of remained organic materials, polysilazane such as perhydropolysilazane and organopolysilazane; polysiloxane such as silsesquioxane; and the like are preferred. From the viewpoint of high gas barrier capabilities, and maintaining the barrier capabilities even at the time of bending and the conditions of high temperature and high humidity, polysilazane is more preferred, and perhydropolysilazane is particularly preferred.

Polysilazane is a polymer having a silicon-nitrogen bond, and a ceramic precursor inorganic polymer having Si—N, Si—H, and N—H bonds for a ceramic such as SiO₂, Si₃N₄, SiOₓN_{y}, and an intermediate solid solution therebetween.

In detail, polysilazane preferably has the following structure.

[Chemical Formula 1]

—[Si(R₁)(R₂)—N(R₃)]ₙ- General Formula (I):

In the above General Formula (I), R₁, R₂, and R₃ each independently represent a hydrogen atom, a substituted or unsubstituted alkyl group, aryl group, vinyl group, or (trialkoxysilyl)alkyl group. At this time, R₁, R₂, and R₃ may be respectively the same or different from each other. Here, as an alkyl group, there may be a linear, branched, or cyclic alkyl group having 1 to 8 carbon atoms. In more detail, there may be a methyl group, an ethyl group, a n-propyl group, an isopropyl group, a n-butyl group, an isobutyl group, a sec-butyl group, a tert-butyl group, a n-pentyl group, an isopentyl group, a neopentyl group, a n-hexyl group, a n-heptyl group, a n-octyl group, a 2-ethylhexyl group, a cyclopropyl group, a cyclopentyl group, a cyclohexyl group, and the like. In addition, as an aryl group, there may be an aryl group having 6 to 30 carbon atoms. In more detail, there may be non-condensed hydrocarbon groups such as a phenyl group, a biphenyl group, and a terphenyl group; and condensed polycyclic hydrocarbon groups such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranthenyl group, an acephenanthrylenyl group, an aceanthrylenyl group, a triphenylenyl group, a pyrenyl group, a chrysenyl group, and a naphthacenyl group. As a (trialkoxysilyl)alkyl group, there maybe an alkyl group having 1 to 8 carbon atoms, which has a silyl group substituted by an alkoxy group having 1 to 8 carbon atoms. In more detail, there may be a 3-(triethoxysilyl)propyl group, a 3-(trimethoxysilyl)propyl group, and the like. Substituents that optionally present on the R₁ to R₃ are not particularly limited, and examples thereof may include an alkyl group, a halogen atom, a hydroxyl group (—OH), a mercapto group (—SH), a cyano group (—CN), a sulfo group (—SO₃H), a carboxyl group (—COOH), a nitro group (—NO₂), and the like. In addition, substituents present in some cases do not become the same as the R₁ to R₃ to be substituted. For example, when the R₁ to R₃ are an alkyl group, they are not further substituted with an alkyl group. Among them, preferably, R₁, R₂, and R₃ represent a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group, or a 3-(trimethoxysilyl propyl) group.

In addition, in the above General Formula (I), n represents an integer, and polysilazane having the structure represented by General Formula (I) is preferably determined to have the number average molecular weight of 150 to 150,000 g/mol.

For the compounds having the structure represented by the above General Formula (I), one preferred embodiment is perhydropolysilazane, in which all of R₁, R₂, and R₃ represent hydrogen atoms.

In addition, polysilazane has the structure represented by the following General Formula (II).

[Chemical Formula 2]

—[Si(R_{1′})(R_{2′})—N(R_{3′})]_{n′}—[Si(R_{4′})(R_{5′})—N(R_{6′})]ₚ— General Formula (II):

In the above General Formula (II), R_{1′}, R_{2′}, R_{3′}, R_{4′}, R_{5′} and R_{6′} each independently represent a hydrogen atom, a substituted or unsubstituted alkyl group, aryl group, vinyl group, or (trialkoxysilyl)alkyl group. At this time, R_{1′}, R_{2′}, R_{3′}, R_{4′}, R_{5′} and R_{6′} are respectively the same or different from each other. As described above, the substituted or unsubstituted alkyl group, aryl group, vinyl group, or (trialkoxysilyl)alkyl group are the same as defined in the above General Formula (I), and thus, the description about them will not be provided.

In addition, in the above General Formula (II), n′ and p are integers, and polysilazane having the structure represented by General Formula (II) is preferably determined to have the number average molecular weight of 150 to 150,000 g/mol. In addition, n′ and p may be the same or different from each other.

Among the polysilazanes of the above General Formula (II), the compound, in which R_{1′}, R_{3′}, and R_{6′} each represent hydrogen atoms, and R_{2′}, R_{4′}, and R_{5′} each represent methyl groups; the compound, in which R_{1′}, R_{3′}, and R_{6′} each represent hydrogen atoms, R_{2′} and R_{4′} each represent methyl groups, and R_{5′} represents a vinyl group; and the compound, in which R_{1′}, R_{3′}, R_{4′}, and R_{6′} each represent hydrogen atoms, and R_{2′} and R_{5′} each represent methyl groups are preferred.

In addition, polysilazane has the structure represented by the following General Formula (III).

[Chemical Formula 3]

—[Si(R_{1″})(R_{2″})—N(R_{3″})]_{n″}—[Si(R_{4″})(R_{5″})—N(R_{6″})]_{p″}—[Si(R_{7″})(R_{8″})—N(R_{9″})]_{q} General Formula (III):

In the above General Formula (III), R_{1″}, R_{2″}, R_{3″}, R_{4″}, R_{5″}, R_{6″}, R_{7″}, R_{8″}, and R_{9″} each independently represent a hydrogen atom, a substituted or unsubstituted alkyl group, aryl group, vinyl group, or (trialkoxysilyl)alkyl group. At this time, R_{1″}, R_{2″}, R_{3″}, R_{4″}, R_{5″}, R_{6″}, R_{7″}, R_{8″}, and R_{9″} may be respectively the same or different from each other. As described above, the substituted or unsubstituted alkyl group, aryl group, vinyl group, or (trialkoxysilyl)alkyl group are the same as defined in the above General Formula (I), and thus, the description about them will not be provided.

In addition, in the above General Formula (III), n″, p″, and q represent integers, and polysilazane having the structure represented by General Formula (III) is preferably determined to have the number average molecular weight of 150 to 150,000 g/mol. In addition, n″, p″, and q may be the same or different from each other.

Among the polysilazane of the above General Formula (III), the compound, in which R_{1″}, R_{3″}, and R_{6″} each represent hydrogen atoms, R_{2″}, R_{4″}, R_{5″}, and R₈″ each represent methyl groups, R_{9″} represents a (triethoxysilyl)propyl group, and R_{7″} represents an alkyl group or a hydrogen atom, is preferred.

Meanwhile, for the organopolysilazane, in which a hydrogen atom moiety binding to its Si is partially substituted with an alkyl group and the like, by having an alkyl group such as a methyl group, the adhesive property with the substrate that is a base is improved, and also, it is possible to impart the toughness to the ceramic film by hard and brittle polysilazane so as to have the advantage of suppressing the generation of cracks even in the case of making (average) film thickness more thick. Therefore, in accordance with the intended application, these perhydropolysilazane and organopolysilazane may be properly selected, mixed, and then, used.

Perhydropolysilazane is presumed to have a structure with a linear structure and a cyclic structure centering on the 6 and 8-membered rings. The molecular weight thereof is about 600 to 2, 000 (polystyrene conversion) as a number average molecular weight (Mn), there maybe a liquid or solid substance, and the state thereof depends on the molecular weight thereof.

Polysilazane is commercially available in a solution state dissolved in an organic solvent, and thus, it is possible to use a commercial product as it is as a coating solution for forming a first barrier layer. As the commercial product of polysilazane solution, there may be AQUAMICA (Registered Trademark) NN120-10, NN120-20, NAX120-20, NN110, NN310, NN320, NL110A, NL120A, NL120-20, NL150A, NP110, NP140, SP140, and the like, manufactured by, AZ Electronic Materials Co., Ltd.

Other examples of polysilazane capable of being used in the present invention are not particularly limited, but examples thereof may include polysilazanes that become ceramic at a low temperature such as silicon alkoxide additional polysilazane (JP H05-238827 A) obtained by reacting silicon alkoxide with the polysilazane, glycidol additional polysilazane (JP H06-122852 A) obtained by reacting glycidol with the polysilazane, alcohol additional polysilazane (JP H06-240208 A) obtained by reacting alcohol with the polysilazane, metal carboxylate additional polysilazane (JP H06-299118 A) obtained by reacting metal carboxylate with the polysilazane, acethylacetonate complex additional polysilazane (JP H06-306329 A) obtained by reacting acetylacetonate complex including a metal with the polysilazane, and metal fine particles additional polysilazane (JP H07-196986 A) obtained by adding metal fine particles.

When using polysilazane, the content of polysilazane in the first barrier layer before the conversion treatment may be 100% by weight with respect to 100% by weight of the total weight of the first barrier layer. In addition, when the first barrier layer includes things other than polysilazane, the content of polysilazane in the layer is preferably 10% by weight or more and 99% by weight or less, more preferably 40% by weight or more and 95% by weigh or less, and still more preferably 70% by weight or more and 95% by weight or less.

A forming method by the applying method of the first barrier layer as described above is not particularly limited, and the known method may be applied. However, the method including applying the coating solution for forming the first barrier layer, which includes a silicon compound and, if necessary, a catalyst in an organic solvent, by the known wet applying method; evaporating and removing the solvent; and then, performing the converison treatment is preferred.

(Coating Solution for Forming First Barrier Layer)

A solvent for preparing the coating solution for forming the first barrier layer is not particularly limited as long as it can solve the silicon compound. However, the organic solvent without water and a reactive group (for example, a hydroxyl group, an amine group, or the like) that easily react with the silicon compound, which is inert to the silicon compound, is preferred, and an aprotic organic solvent is more preferred. In detail, as a solvent, there may be an aprotic solvent; a hydrocarbon solvent such as aliphatic hydrocarbon, alicyclic hydrocarbon, and aromatic hydrocarbon, for example, pentane, hexane, cyclohexane, toluene, xylene, solvesso, and turpentine; a halogen hydrocarbon solvent such as methylene chloride and trichloroethane; esters such as ethyl acetate and butyl acetate; ketones such as acetone and methyl ethyl ketone; ethers such as alicyclic ether and aliphatic ether such as dibutyl ether, dioxane, and tetrahydrofuran; for example, tetrahydrofuran, dibutyl ether, and mono- and polyalkylene glycol dialkyl ether (diglymes); and the like. The solvents may be selected in accordance with the objects such as the solubility of a silicon compound and the evaporation rate of a solvent, and may be used singly or as a mixture form in combination of two or more types thereof.

The concentration of a silicon compound in the coating solution for forming a first barrier layer is not particularly limited and it depends on the pot life of the coating solution or the film thickness of a layer. It is preferably 1 to 80% by weight, more preferably 5 to 50% by weight, and particularly preferably 10 to 40% by weight.

The coating solution for forming a first barrier layer conversion. As a catalyst capable of being applied for the present invention, a basic catalyst is preferred, and especially, there maybe amine catalysts such as N,N-diethyl ethanolamine, N,N-dimethyl ethanolamine, triethanolamine, triethylamine, 3-morpholinopropylamine, N,N,N′,N′-tetramethyl-1,3-diaminopropane, and N,N,N′,N′-tetramethyl-1,6-diaminohexane, metal catalysts, for example, Pt compounds such as Pt acetylacetonate, Pd compounds such as propionic acid Pd, and Rh compounds such as Rh acetylacetonate, and N-heterocyclic compounds. Among them, amine catalysts are preferably used. At this time, the concentration of catalyst added is preferably in the range of 0.1 to 10% by weight, and more preferably in the range of 0.5 to 7% by weight, with respect to the silicon compound (Example: 1% by weight). By setting the added amount of a catalyst in the above-described range, it is possible to avoid excess silanol formation by rapid progress of a reaction, the decrease in a film density, the increase in a film defect, and the like.

For the coating solution for forming a first barrier layer, if necessary, the additives to be listed below as an example maybe used. Examples thereof may include cellulose ethers and cellulose esters; natural resins such as ethyl cellulose, nitrocellulose, cellulose acetate, and cellulose acetate butyrate, for example; synthetic resins such as a rubber and a rosin resin, for example; condensation resins such as polymerization reins, for example; aminoplast, especially, a urea resin, a melamine formaldehyde resin, an alkyd resin, an acrylic resin, polyester or modified polyester, epoxide, polyisocyanate or blocked polyisocyanate, polysiloxane, and the like.

In addition, as disclosed in JP 2005-231039 A, a sol gel method may be used for forming a first barrier layer. The coating solution that is used for forming a converting layer by the sol-gel method preferably includes a silicon compound and at least one of a polyvinyl alcohol resin, and an ethylene • vinyl alcohol copolymer. In addition, it preferably includes a sol-gel method catalyst, an acid, water, and an organic solvent. For the sol-gel method, a converting layer may be obtained by polycondensation using such a coating solution. As a silicon compound, alkoxide (alkoxysilane) represented by R^{A}_{O}Si(OR^{B})ₚ is preferably used. Here, R^{A} and R^{B} each independently represent an alkyl group having 1 to 20 carbon atoms, O represents an integer of 0 or more, and p represents an integer of 1 or more. Specific examples of the alkoxysilane above may include, for example, tetramethoxysilane (Si(OCH₃)₄), tetraethoxysilane (Si(OC₂H₅)₄), tetrapropoxysilane (Si(OC₃H₇)₄), tetrabutoxysilane (Si(OC₄H₉)₄), and the like. When a polyvinyl alcohol resin and an ethylene • vinyl alcohol copolymer are combined and then used for the coating solution, the combined ratio of each of them is preferably polyvinyl alcohol resin:ethylene • vinyl alcohol copolymer=10:0.05 to 10:6 as a weight ratio. In addition, as the content of the polyvinyl alcohol resin and/or ethylene • vinyl alcohol copolymer in the coating solution, it is preferably prepared to have the combined ratio in the range of 5 to 500 parts by weight and preferably in the range of about 20 to 200 parts by weight with respect to 100 parts by weight of the total amount of the silicon compound. As the polyvinyl alcohol resin, in general, the polyvinyl alcohol resin obtained by the saponification of polyvinyl acetate may be used. As the polyvinyl alcohol resin, any one of a partially saponified polyvinyl alcohol resin having a dozen percent of remained acetic acid group, a completely saponified polyvinyl alcohol without an acetic acid group, or a modified polyvinyl alcohol resin having a modified OH group may be used. As specific examples of the polyvinyl alcohol resin, KURARAY POVAL (Registered Trademark) manufactured by Kuraray Co., Ltd., GOHSENOL (Registered Trademark) manufactured by The Nippon Synthetic Chemical Industry Co., Ltd., and the like may be used. In addition, in the present invention, as an ethylene•vinylalcohol copolymer, a saponified product of the copolymer of ethylene and vinyl acetate, that is, the thing obtained by the saponification of an ethylene-vinyl acetate random copolymer, may be used. In detail, the products including a partially saponified product with a dozen mol % of remained acetic acid groups to a completely saponified product with only several mol % of remained acetic acid groups or without acetic acid groups, which have the preferred saponification degree of 80 mol % or more, more preferably 90 mol % or more, and still more preferably 95 mol % or more from the viewpoint of gas barrier properties, may be preferably used, but the present invention is not limited thereto. In addition, it is preferable that the content of the repeating unit derived from ethylene in the ethylene•vinyl alcohol copolymers (hereinafter, referred to as “the content of ethylene”) is generally 0 to 50 mol %, and preferably 20 to 45 mol %. As specific examples of the ethylene•vinyl alcohol copolymer, there may be EVAL (Registered Trademark) EP-F101 (the content of ethylene: 32 mol %) manufactured by Kuraray Co., Ltd., SOARNOL (Registered Trademark) D2908 (the content of ethylene: 29 mol %) manufactured by The Nippon Synthetic Chemical Industry Co., Ltd., and the like. As a sol-gel method catalyst, mainly, a polycondensation catalyst, a tertiary amine that is substantially insoluble in water but soluble in an organic solvent is used. In detail, examples thereof may include N,N-dimethylbenzylamine, tripropylamine, tributylamine, tripentylamine, and the like. In addition, the acid is used as a catalyst of the sol-gel method, mainly, a catalyst for hydrolyzing alkoxide, silane coupling agent, and the like. Examples of the acid may include mineral acids such as a sulfuric acid, a hydrochloric acid, and a nitric acid, and organic acids such as an acetic acid and a tartaric acid, and the like. In addition, the coating solution may preferably include water in the ratio of 0.1 to 100 mol and preferably 0.8 to 2 mol with respect to 1 mol of the total molar amount of the alkoxide.

Examples of the organic solvent used for the coating solution according to the sol-gel method may include methyl alcohol, ethyl alcohol, n-propyl alcohol, isopropyl alcohol, n-butanol, and the like. In addition, as the ethylene • vinyl alcohol copolymer that is solubilized in a solvent, for example, those commercially available as SOARNOL (Registered Trademark) may be used. In addition, for example, silane coupling agent, and the like, may be added in the coating method by the sol-gel method.

(Method for Applying Coating Solution for Forming First Barrier Layer)

As a method for applying a coating solution for forming a first barrier layer, the conventionally known proper wet applying method may be employed. Specific examples thereof may include a spin coating method, a roll coating method, a flow coating method, an inkjet method, a spray coating method, a printing method, a dip-coating method, a flexible film-forming method, a bar-coating method, a gravure printing method, and the like.

The applying thickness may be properly determined according to the objects. For example, for the applying thickness per one layer of a first barrier layer, the thickness after drying is preferably about 10 nm to 10 μm, more preferably 15 nm to 1 μm, and still more preferably 20 to 500 nm (Example: 150 nm). When the film thickness is 10 nm or more, it is possible to obtain sufficient barrier properties, and when it is 10 μm or less, it is possible to obtain stable coating properties at the time of forming a layer, and also, it is possible to implement high light transmittance.

After applying a coating solution, it is preferable to dry a coating film. By drying the coating film, it is possible to remove an organic solvent included in the coating film. At this time, the organic solvent included in the coating film may be completely dried, but some of them may be remained. Even in the case of remaining some of organic solvents, it is possible to obtain suitable first barrier layer. In addition, the remained solvent may be removed later.

The temperature for drying the coating film is varies depending on the substrates applied, but is preferably 50 to 200° C. For example, when the polyethylene terephthalate substrate having the glass transition temperature (Tg) of 70° C. is used as a substrate, the drying temperature is set to be 150° C. or lower considering the deformation of the substrate by heat. The temperature may be set by using a hot plate, an oven, a furnace, and the like. The drying time is preferably set to be a short time, and for example, when the drying temperature is 150° C., it is preferably set to be within 30 minutes. In addition, as a drying atmosphere, any one of conditions such as air atmosphere, nitrogen atmosphere, argon atmosphere, vacuum atmosphere, reduced pressure atmosphere with a controlled oxygen concentration and the like, may be used.

For the coating film obtained by applying the coating solution for forming a first barrier layer, a process for removing water may be included before the conversion treatment or during the conversion treatment. As a method for removing water, a form to be dehumidified while maintaining a low humidity environment is preferred. Since the humidity at the low humidity environment changes depending on the temperature, a preferred form of the relationship between the temperature and humidity can be defined by the dew-point temperature. The preferred dew-point temperature is 4° C. or lower (temperature of 25° C./humidity of 25%), and the more preferred dew-point temperature is −5° C. (temperature of 25° C./humidity of 10%) or lower. Preferably, the maintaining time is properly set depending on the film thickness of a first barrier layer. When the film thickness of the first barrier layer is 1.0 μm or less, it is preferable that the dew-point temperature is −5° C. or lower and the maintaining time is 1 minute or more. In addition, the lower limit of the dew-point temperature is not particularly limited, but generally, −50° C. or higher, and preferably −40° C. or higher. By removing water before the conversion treatment or during the conversion treatment, it is preferred from the viewpoint of promoting the dehydration reaction of the first barrier layer that is converted into silane.

<Conversion Treatment of First Barrier Layer Formed by Coating Method>

The conversion treatment of the first barrier layer formed by an coating method in the present invention indicates the conversion reaction of a silicon compound into silicon oxide, silicon oxynitride or the like. In detail, the conversion treatment indicates the treatment for forming an inorganic thin film in the level capable of contributing to the exhibition of gas barrier properties of the gas barrier film of the present invention as a whole.

As the conversion reaction of a silicon compound into silicon oxide or silicon oxynitride, the known methods may be properly selected, and then, employed. In detail, as the conversion treatment, there may be a plasma treatment, a UV ray irradiation treatment, and a heating treatment. However, when the conversion is performed by a heating treatment, a high temperature of 450° C. or higher is required to form a silicon oxide film or a silicon oxynitride layer by the substitution reaction of a silicon compound, and thus it is difficult to be applied for a flexible substrate such as a plastic. Therefore, it is preferable that the heating treatment is performed by being combined with other conversion treatments.

Therefore, from the viewpoint of adaptation to a plastic substrate, the conversion reaction by a UV ray irradiation treatment or a plasma treatment capable of performing the conversion reaction at a lower temperature is preferred as the conversion treatment.

(Plasma Treatment)

In the present invention, as the plasma treatment capable of being used as the conversion treatment, the known method may be used, but preferably, an atmospheric pressure plasma treatment, and the like, may be used. For the atmospheric pressure plasma CVD method, in which the plasma CVD treatment is performed in the vicinity of atmospheric pressure, as compared with the plasma CVD under vacuum, it is not necessary to make decompression, the productivity thereof is high, and the plasma density is high, thereby increasing the rate of film-forming. In addition, as compared with the condition of a general CVD method, since the mean free process of gas is very short under a high pressure condition of atmospheric pressure, it is possible to obtain an extremely uniform film.

In the case of an atmospheric pressure plasma treatment, a nitrogen gas or the gas including Group 18 elements in the long form of the periodic table, specifically, helium, neon, argon, krypton, xenon, radon, and the like are used as a discharge gas. Among them, nitrogen, helium, or argon is preferably used, and especially, nitrogen is low-priced, and preferred.

(Heating Treatment)

The conversion treatment of the coating film including a silicon compound may be effectively conducted by being combined with other conversion treatments, preferably, an excimer irradiation treatment to be described below, and then, by performing the heating treatment.

In addition, when forming a layer using a sol-gel method, the heating treatment is preferably used. A condensation may be performed to form a first barrier layer by performing the heating and drying under the heating condition, in which the temperature is preferably 50 to 300° C. and more preferably 70 to 200° C. and the time is preferably 0.005 to 60 minutes and more preferably 0.01 to 10 minutes.

As a heating treatment, there are mentioned a method for heating a coating film by a heat conduction by bring a substrate into contact with a heating element such as a heat block; a method for heating the atmosphere by an external heater by the resistance wire or the like; a method using the light in the infrared region such as an IR heater; and the like, but the present invention is not limited thereto. In addition, a method for maintaining the smoothness of a coating film including a silicon compound may be properly selected.

The temperature of a coating film at the time of performing the heating treatment is properly adjusted in the range of 50 to 250° C., and more preferably in the range of 50 to 120° C.

In addition, the heating time is preferably in the range of 1 second to 10 hours, and more preferably in the range of 10 seconds to 1 hour.

(UV Ray Irradiation Treatment)

As one of the methods for performing conversion treatment, the treatment by UV ray irradiation is preferred. The ozone or active oxygen atoms produced by UV rays (equivalent to UV light) have high oxidation ability, and thus, it is possible to form a silicon oxide film or silicon oxynitride film having high denseness and insulating properties at a low temperature.

Since a substrate is heated by such a UV ray irradiation, and thus, O₂ or H₂O contributing to ceramization (silica conversion), an UV absorber, and polysilazane itself are excited and are activated, the polsilazane is excited and the cermaiztion of polysilazane is promoted, thereby further making the first barrier layer thus obtained dense. The UV irradiation is effective at any time when it comes to be performed after forming a film.

For the UV ray irradiation treatment, it is also possible to use any one of UV ray-generating devices that are commonly used.

In addition, the UV ray disclosed in the present invention generally refers to an electromagnetic wave having the wavelength of 10 to 400 nm, but in the case of an UV ray irradiation treatment other than a vacuum UV ray (10 to 200 nm) treatment to be disclosed below, it uses preferably the UV rays of 210 to 375 nm.

For the UV ray irradiation, the irradiation intensity or irradiation time is preferably set within the range, in which the substrate carrying the first barrier layer to be irradiated is not damaged.

When using a plastic film as a substrate, for example, the lamp of 2 kW (80 W/cm×25 cm) is used and the distance between a substrate and an UV ray irradiation lamp is set so that the intensity of the substrate surface is 20 to 300 mW/cm², and preferably 50 to 200 mW/cm², and then, the irradiation may be performed for 0.1 second to 10 minutes.

In general, when the temperature of a substrate is 150° C. or higher at the time of UV ray irradiation treatment, in the case of a plastic film, and the like, the properties of a substrate are damaged, that is, the substrate is deformed or the strength thereof is deteriorated. However, in the case of the film having high heat resistance, for example, polyimide, it is possible to perform the conversion treatment at a higher temperature. Therefore, there is no upper limit of the temperature of a substrate at the time of this UV ray irradiation, and the temperature thereof may be properly set according to the type of a substrate by those skilled in the art. In addition, the atmosphere of UV ray irradiation is not particularly limited, and UV ray irradiation may be performed in the air.

As a means for generating such UV rays, for example, there may be a metal halide lamp, a high pressure mercury lamp, a low pressure mercury lamp, a xenon arc lamp, a carbon arc lamp, an excimer lamp (a single wavelength of 172 nm, 222 nm, or 308 nm, for example, manufactured by Ushio Inc. or manufactured by M. D. Com Inc.), an UV light laser, and the like, but the present invention is not limited thereto. In addition, when the first barrier layer is irradiated with the generated UV rays, it is preferable that the UV rays from the generation source are reflected by a reflection plate, and then, applied to the first barrier layer from the viewpoint of achieving the improvement of efficiency and uniform irradiation.

The UV ray irradiation can be applied in a batch treatment and also continuous treatment, and may be properly selected by the shape of the substrate to be used. For example, in the case of the batch treatment, the laminate having a first barrier layer on the surface thereof may be treated in a UV rays burning furnace having an UV rays-generating source as described above. The UV rays burning furnace itself is generally known, and for example, the UV rays burning furnace manufactured by Eye Graphics Co., Ltd. may be used. In addition, when the laminate having a first barrier layer on the surface thereof is in the shape of long-film, while conveying the laminate, the ceramization of the laminate may be performed by continuously irradiating with UV rays in a dry zone having the UV rays-generating source as described above. The time that is required for the UV ray irradiation depends on the concentration and the composition of the first barrier layer and the substrate used, but generally 0.1 second to 10 minutes and preferably 0.5 second to 3 minutes.

(Vacuum UV Ray Irradiation Treatment: Excimer Irradiation Treatment)

In the present invention, the most preferred conversion treatment method is the treatment by a vacuum UV ray irradiation (excimer irradiation treatment). The treatment by the vacuum UV ray irradiation uses the light energy of 100 to 200 nm that is higher than interatomic bonding strength in a polysilazane compound, and preferably uses the light energy having the wavelength of 100 to 180 nm. The method progresses the oxidation reaction by active oxygen or ozone while directly cutting interatomic bond by the action of only photons called a photon process, in which the formation of silicon oxide film is performed at a relatively low temperature (about 200° C. or lower). In addition, when the excimer irradiation treatment is performed, it is preferable to perform a heating treatment together as described above, and at this time, the detailed content of the heating treatment condition is as described above.

The radiation source of the present invention may be used as long as it generates the light having the wavelength of 100 to 180 nm, but more preferably, may be an excimer radiator (for example, an Xe excimer lamp) having the maximum radiation at about 172 nm, a low pressure mercury lamp having the emission line at about 185 nm, a medium pressure and high pressure mercury vapor lamp having the wavelength component of 230 nm or less, and an excimer lamp having the maximum radiation at about 222 nm.

Among them, the Xe excimer lamp radiates a short wavelength of UV rays of 172 nm as a single wavelength, and thus, the luminous efficiency is excellent. This light has large absorption coefficient of oxygen, and thus, can generate radical oxygen atom species or ozone in a high concentration with a small amount of oxygen.

In addition, it is known that the light energy of short wavelength of 172 nm has high ability for dissociating the binding of the organic materials. The conversion of polysilazane coating film may be realized in a short time by this active oxygen or ozone, and high energy of UV ray radiation.

Since the excimer lamp has high efficiency of light generation, it is possible to light with a low power application. In addition, it does not emit a long wavelength that is a factor for increasing the temperature by light, and irradiates with the energy in a UV ray region, that is, with a short wavelength. Therefore, it is characterized by suppressing the increase in the temperature of the surface of a solution-morphism object. Therefore, it is suitable for the material for a flexible film such as PET that is easily influenced by heat.

It is preferable that for the reaction at the time of UV ray irradiation, oxygen exists. However, for the vacuum UV rays, there may be the absorption by oxygen, and thus, it is easy to decrease the efficiency in the UV ray irradiation process. Therefore, the vacuum UV ray irradiation is preferably performed in the state of low oxygen concentration and vapor concentration as possible. In other words, the oxygen concentration at the time of the vacuum UV ray irradiation is preferably 10 to 20,000 vol ppm, and more preferably 50 to 10,000 vol ppm. In addition, the vapor concentration during the conversion process is preferably in the range of 1000 to 4000 vol ppm.

The gas that is used at the time of the vacuum UV ray irradiation and satisfies the irradiation atmosphere is preferably a dried inert gas, and especially, preferably a dried nitrogen gas from the viewpoint of cost. The oxygen concentration may be adjusted by measuring the flow rate of oxygen gas and inert gas that are introduced into the irradiation main body, and then, changing the ratio of flow rate.

For the vacuum UV ray irradiation process, the intensity illuminate of vacuum UV rays on the surface of a coating film that is received by a polysilazane coating film is preferably 1 mW/cm² to 10 W/cm², more preferably 30 mW/cm² to 200 mW/cm², and still more preferably 50 mW/cm² to 160 mW/cm². When it is less than 1 mW/cm², there is a concern that the conversion efficiency is greatly reduced. When it exceeds 10 W/cm², there is a concern that the ablation on a coating film may occur or a substrate may be damaged.

The irradiation energy amount (irradiation dose) of vacuum UV rays on the surface of a coating film is preferably 10 to 10000 mJ/cm², more preferably 100 to 8000 mJ/cm², and still more preferably 200 to 6000 mJ/cm² (Example: 6000 mJ/cm²). When it is less than 10 mJ/cm², there is a concern that the conversion is insufficient. When it exceeds 10000 mJ/cm², there is a concern that the cracks may be generated by excess conversion and a substrate may be deformed by heat.

The vacuum UV rays that are used for the conversion may be generated by the plasma formed with gas including at least one type of CO, CO₂, and CH₄. In addition, as the gas including at least one type of CO, CO₂, and CH₄ (hereinafter, also called carbon-containing gas), the carbon-containing gas may be used singly, but a small amount of carbon-containing gas, and noble gas or H₂ as a main gas may be preferably used. As a way for producing plasma, there may be capacity coupling plasma and the like.

Next, when the silicon compound is perhydropolysilazane, which is a preferred embodiment, the reaction mechanism, in which it is presumed that silicon oxynitride or silicon oxide is generated from perhydropolysilazane in the vacuum UV ray irradiation process, will be described below.

(I) Dehydrogenation and Formation of Si—N Bond According to Dehydrogenation

It is considered that the Si—H bond or N—H bond in perhydropolysilazane may be relatively easily cut by the excitation by the vacuum UV ray irradiation, and thus, may be re-bound as Si—N under an inert atmosphere (the dangling bonds of Si are formed in some cases). In other words, it is not oxidized, and then, cured as the composition of SiN_{y}. In this case, the cleavage of polymer main chain does not occur. The cleavage of Si—H bond or N—H bond is promoted by the presence of a catalyst or by heating. The cleaved H is discharged to the outside of the film as H₂.

(II) Formation of Si—O—Si Bond by Hydrolysis and Dehydration Condensation

The Si—N bond in perhydropolysilazane is hydrolyzed by water, and thus, the polymer main chain is cleaved to form Si—OH. Two Si—OH bonds are dehydration-condensed to form a Si—O—Si bond and then cure. This reaction is generated in the air, but it is considered that, the vapor generated as outgas from the substrate by the heat of irradiation becomes a main water source during the vacuum UV ray irradiation under the inert atmosphere. When excessive water is produced, the Si—OH that cannot be dehydration-condensed is remained, and thus, the cured film having low gas barrier properties, which is represented by the composition of SiO_{2.1} to SiO_{2.3} is produced.

(III) Direct Oxidation by Singlet Oxygen and Formation of Si—O—Si Bond

During the vacuum UV ray irradiation, when the appropriate amount of oxygen exists in the atmosphere, singlet oxygen having very strong oxidizing powder is formed. H or N in perhydropolysilazane is changed into O to form a Si—O—Si bond, and then, cure. It is considered that the recombination of the bond may be generated by performing the cleavage of the polymer main chain in some cases.

(IV) Oxidation With Cleavage of Si—N Bond by Vacuum UV Ray Irradiation•Excitation

It is considered that since the energy of vacuum UV rays is higher than the energy of Si—N bond in perhydropolysilazane, Si—N bond is cleaved, and then, when oxygen source such as oxygen, ozone, and water and the like exists, the oxidation is generated to form a Si—O—Si bond or Si—O—N bond. It is considered that the recombination of the bond may be generated by performing the cleavage of the polymer main chain in some cases.

The composition of silicon oxynitride of the layer including polysilazane after irradiating vaccum UV lays to a layer may be adjusted by controlling the oxidation state through properly combining the oxidation mechanisms of (I) to (IV) as described above.

Here, in the case of polysilazane that is preferable as a silicon compound, the Si—H and N—H bonds are cleaved and Si—O bond is generated in the silica conversion (conversion treatment) to convert into ceramic such as silica, but the degree of this conversion may be estimated semi-quantitatively from the ratio of SiO/SiN according to Equation (1) defined below by the IR measurement.

[Equation 1]

SiO/SiN ratio=(SiO absorbance after conversion)/(SiN absorbance after conversion) Equation (1)

Here, the SiO absorbance and SiN absorbance are calculated by the absorptions (absorbance) at about 1160 cm⁻¹ and about 840 cm⁻¹, respectively. As the ratio of SiO/SiN increases, the conversion into ceramic that is close to the composition of silica is performed.

Here, the index of the conversion degree into ceramic, the ratio of SiO/SiN, is preferably 0.3 or more, and more preferably 0.5 or more. When it is less than 0.3, there may be the cases in which it is difficult to obtain the expected gas barrier properties. In addition, as a method for measuring the silica conversion rate (x for SiOₓ), for example, the silica conversion rate may be measured by a XPS method.

The film composition of the first barrier layer may be measured by measuring the ratio of atomic composition using an XPS surface analyzing device. In addition, it may be measured by cutting the first barrier layer, and then, by measuring the ratio of atomic composition for the cut side thus obtained with the XPS surface analyzing device.

The above-described first barrier layer may be a single layer or may have the structure of laminating two or more layers. At this time, when the first barrier layer has the structure of laminating two or more layers, the respective first barrier layers may have the same composition or different composition from each other. In addition, when the first barrier layer has the structure of laminating two or more layers, the first barrier layer may be constituted of only the layer formed by a vacuum film-forming method, may be constituted of only the layer formed by a coating method, and may be constituted of the combination of layers formed by the vacuum film-forming method and coating method.

In addition, the first barrier layer preferably includes a nitrogen element or carbon element, from the viewpoint of stress relaxation properties or the absorption of UV rays that is used for forming a second barrier layer described later. The properties such as stress relaxation and UV rays absorption are exhibited by including these elements, and the effect on improving gas barrier properties may be obtained by improving the adhesion between the first barrier layer and the second barrier layer, which are preferred.

The chemical composition in the first barrier layer may be controlled by the type and amount of a silicon compound at the time of forming the first barrier layer, the conditions at the time of converting the layer including the silicon compound, and the like.

[Second Barrier Layer]

The second barrier layer is characterized in that it is a layer provided on the upper side of a first barrier layer, or between a substrate and the first barrier layer, and includes silicon atoms, oxygen atoms, and at least one added element selected from the group consisting of elements of Groups 2-14 of the long form of the periodic table (excluding silicon and carbon), in which the abundance ratio of oxygen atoms to silicon atoms (OSi) is 1.4 to 2.2, and the abundance ratio of nitrogen atoms to silicon atoms (N/Si) is 0 to 0.4.

First, the second barrier layer according to the present invention is characterized by including at least one element (also called “added element”) selected from the group consisting of elements of Groups 2-14 of the long form of the periodic table (excluding silicon and carbon). By having such a constitution, it is possible to obtain the gas barrier film having excellent initial gas barrier capabilities, and also, excellent durability to the environmental change involving the temperature change.

Examples of the added element may include beryllium (Be), boron (B), magnesium (Mg), aluminum (Al), calcium (Ca), scandium (Sc), titanium (Ti), vanadium (V), chromium (Cr), mangan (Mn), iron (Fe), cobalt (Co), nickel (Ni), copper (Cu), zinc (Zn), gallium (Ga), germanium (Ge), strontium (Sr), yttrium (Y), zirconium (Zr), niobium (Nb), molybdenum (Mo), technetium (Tc), ruthenium (Ru), rhodium(Rh), palladium(Pd), silver (Ag), cadmium (Cd), indium (In), tin (Sn), barium (Ba), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), hafnium (Hf), tantalum (Ta), tungsten (W), rhenium (Re), osmium (Os), iridium (Ir), platinum (Pt), gold (Au), mercury (Hg), thallium (Tl), lead (Pb), radium (Ra), and the like.

Among these elements, boron (B), magnesium (Mg), aluminum (Al), calcium (Ca), titanium (Ti), chromium (Cr), chromium (Mn), iron (Fe), cobalt (Co), copper (Cu), zinc (Zn), gallium (Ga), zirconium (Zr), silver (Ag), and indium (In) are preferred; boron (B), magnesium (Mg), aluminum (Al), calcium (Ca), titanium (Ti), zinc (Zn), gallium (Ga), germanium (Ge), zirconium (Zr), and indium (In) are more preferred; boron (B), magnesium (Mg), aluminum (Al), calcium (Ca), titanium (Ti), zinc (Zn), and zirconium (Zr) is still more preferred; boron (B), magnesium (Mg), aluminum (Al), calcium (Ca), iron (Fe), gallium (Ga), and indium (In) are still more preferred; boron (B), aluminum (Al), gallium (Ga), and indium (In) are still more preferred; boron (B) and aluminum (Al) are particularly preferred; and aluminum (Al) is most preferred. The elements of Group 13 such as boron (B), aluminum (Al), gallium (Ga), and indium (In) become trivalent atomic value, and thus, have insufficient valence as compared with tetravalent atomic value that is the atomic value of silicon, thereby increasing the flexibility of a film. By this improvement of flexibility, the defects are restored, and the second barrier layer becomes a dense film, thereby improving the gas barrier properties. In addition, by increasing the flexibility, oxygen is supplied into the inside of the second barrier layer, and oxidation is performed into the inner part of the barrier layer. Therefore, it becomes the barrier layer having high oxidation resistance at the state of completing film-forming. In addition, the added elements may exist singly or in the mixture form of two or more types thereof.

In addition, the second barrier layer includes necessarily silicon atoms and oxygen atoms in addition to the above-described added element, and also, is characterized in that the abundance ratio of oxygen atoms to silicon atoms (OSi) is 1.4 to 2.2, and the abundance ratio of nitrogen atoms to silicon atoms (N/Si) is 0 to 0.4.

In the present invention, “the abundance ratio of oxygen atoms to silicon atoms (OSi) of 1.4 to 2.2” means 1.4 to 2.2 of O/Si as the average of the total second barrier layer. Similarly, “the abundance ratio (N/Si) of nitrogen atoms to silicon atoms of 0 to 0.4” means 0 to 0.4 of N/Si as the average of the total second barrier layer.

The case where the abundance ratio of oxygen atoms to silicon atoms (O/Si) in the second barrier layer is less than 1.4 means that oxidation is insufficient, leading to the decrease in durability. Meanwhile, the case where the value of O/Si exceeds 2.2 means that hydrolysis progresses, and thus, water is likely to penetrate. In addition, from the viewpoint of obtaining the gas barrier film having excellent durability, the value of O/Si is preferably 1.6 to 2.1 . Here, as a way for controlling the value of O/Si, the value may be controlled by the conversion treatment to be described below. For example, when the concentration of oxygen is low at the time of the conversion, the value of O/Si tends to be decreased, and when the concentration of oxygen is high at the time of the conversion, the value of O/Si tends to be increased. In addition, when applying to a resin substrate, water is supplied from the resin substrate, and thus, O/Si tends to be increased.

In addition, when the abundance ratio of nitrogen atoms to silicon atoms (N/Si) in the second barrier layer exceeds 0.4, defects tend to be increased. In addition, from the viewpoint of obtaining the gas barrier film having excellent durability, the value of N/Si is preferably 0 to 0.3 and more preferably 0 to 0.2. Here, for example, when irradiating with vacuum UV rays at the time of the conversion as a way for controlling the value of N/Si, as the irradiation energy of vacuum UV rays is large, the value of N/Si tends to be decreased, and as the irradiation energy of vacuum UV rays is small, the value of N/Si tends to be increased.

The O/Si and N/Si may be measured by the following method. That is, the composition profile of the second barrier layer may be obtained by combining an Ar sputtering etching device and X-ray photoelectron spectroscopy (XPS). In addition, the profile distribution in the depth direction may be calculated by corresponding the result of XPS after obtaining the actual film thickness by a TEM (transmission electron microscope) and the film processing by a FIB (focused ion beam) processing device.

In the present invention, the following device and way are used.

(Sputtering Condition)

Ion species: Ar ion

Acceleration voltage: 1 kV

(X-ray photoelectron spectroscopy measurement condition)

Device: ESCALAB-200R manufactured by VG. Scienta Inc. X-ray anode material: Mg

Output: 600 W (acceleration voltage of 15 kV and emission current of 40 mA)

In addition, the resolution of measurement is 0.5 nm, it is obtained by plotting each of element ratios at each of the sampling points in accordance therewith.

(FIB Processing)

Device: SMI2050 manufactured by Seiko Instruments Inc.

Processing ion: (Ga 30 kV)

(TEM Observation)

Device: JEM2000FX (acceleration voltage: 200 kV) manufactured by JEOL Ltd.

Irradiation time of electron beam: 5 seconds to 60 seconds

In addition, in the present invention, the film density of the second barrier layer is preferably 1.5 to 2.5 g/cm³. Since as the film density is high, the synergistic effect of the first layer and the second layer increases, it is preferably 1.7 to 2.5 g/cm³, and more preferably 1.9 to 2.5 g/cm³.

<Formation of Second Barrier Layer>

A method for forming a second barrier layer is not particularly limited, but any one of a dry coating method and a wet coating method disclosed in Non-Patent Document 1 may be used. However, from the viewpoint of improving productivity, a wet coating method is preferably used. Especially, the coating solution (in the present specification, also called “a second coating solution”) including polysilazane, and an added compound including at least one added element selected from the group consisting of elements of Groups 2-14 of the long form of the periodic table (excluding silicon and carbon) is applied to form a coating film (in the present specification, also called “a second coating film”), and then, the second coating film is subjected to the conversion treatment to form a second barrier layer, preferably. Hereinafter, the case of forming a second barrier layer according to such a way as an example will be described.

(Polysilazane)

Specific examples of polysilazane are the same as the content described in the above-described paragraph, “first barrier layer”, and thus, the description about this will not be provided. Among them, from the viewpoint of film-forming ability, low defect such as cracks, the decrease in remained organic materials, the maintenance of barrier capabilities at the time of bending and under the condition of a high temperature and high humidity, and the like, perhydropolysilazane is particularly preferred.

(Added Compound)

A type of an added compound is not particularly limited, but any compounds may be used as an added compound as long as the compounds include the above-described added element.

Examples of an aluminum compound may include anorthoclase, alumina, aluminosilicate, aluminate, sodium aluminate, alexandrite, ammonioleucite, yttrium-aluminum-garnet, melilite, osarizawaite, omphacite, augite, sericite, gibbsite, sanidine, sapphire, aluminum oxide, aluminum hydroxide, aluminum bromide, aluminum dodecaboride, aluminum nitrate, muscovite, aluminum hydroxide, lithium aluminum hydride, sugilite, spinel, diaspore, aluminum arsenide, peacock, microcline, jade pyroxene, cryolite, hornblende, aluminum fluoride, zeolite, brazilianite, vesuvianite, B alumina solid electrolyte, pezzottaite, sodalite, an organic aluminum compound, spodumene, lepidolite, aluminum sulphate, beryl, chlorite, epidote, aluminium phosphide, aluminum phosphate, and the like.

As a magnesium compound, there maybe zinc-melanterite, magnesium sulfite, magnesiumbenzoate, carnallite, magnesium perchlorate, magnesium peroxide, talc, enstatite, olivine, magnesium acetate, magnesium oxide, serpentine, magnesium bromide, magnesium acetate, magnesium hydroxide, spinel, hornblende, augite, magnesium fluoride, magnesium sulfide, magnesium sulfate, magnesite, and the like.

As a calcium compound, there may be aragonite, calcium sulfite, calcium benzoate, Egyptian blue, calcium chloride, calcium hydroxide chloride, calcium chlorate, uvarovite, scheelite, hedenbergite, zoisite, calcium peroxide, calcium superphosphate, calcium cyanamide, calcium hypochlorite, calcium cyanide, calcium bromide, double superphosphate, calcium oxalate, calcium bromate, calcium nitrate, calcium hydroxide, hornblende, augite, calcium fluoride, fluorapatite, calcium iodide, calcium iodate, johannsenite, calcium sulfide, calcium sulphate, actinolite, epidote, epidote, autunite, apatite, calcium phosphate, and the like.

As a gallium compound, there maybe gallium oxide (III), gallium oxyhydroxide (III), galliumnitride, galliumarsenide, gallium (III) iodide, gallium phosphate, and the like.

As a boron compound, there may be boron oxide, boron tribromide, boron trifluoride, boron triiodide, sodium cyanoborohydride, diborane, boric acid, trimethyl borate, borax, borazine, borane, boronic acid, and the like.

As a germanium compound, there may be various organic germanium compounds, an inorganic germanium compound, germanium oxide, and the like.

As an indium compound, there maybe indium oxide, indium chloride, and the like.

As a titanium compound, there may be titanium oxide, titanium chloride, and the like.

As a zirconium compound, there may be zirconium oxide, zirconium chloride, and the like.

As a zinc compound, there maybe zinc oxide, zinc chloride, and the like.

In addition to the above-described various compounds, from the viewpoint of more effectively forming the second barrier layer according to the present invention due to high compatibility with polysilazane, it is preferable to use the alkyl compound and alkoxide compound of an added element as an added compound. In addition, the amide compound of an added element, the imide compound of an added element, or the hydroxide compound of an added element may be used. Here, “the amide compound of an added element”, “the alkoxide compound of an added element”, “the amide compound of an added element”, “the imide compound of an added element”, and “the hydroxide compound of an added element” indicate the compounds having at least one alkyl group, alkoxy group, amide group, imide group, and hydroxyl group that bind to an added element, respectively. In addition, the added compounds may be used singly or in combination of two or more types thereof. In addition, as the added compounds, commercially available products may be used and synthetic products may be used.

As an alkyl compound used as an added compound, the alkyl substituents of various metals may be used, but since they are generally commercially available, trimethylaluminum, triethylaluminum, diisobutylaluminium hydride, diethyl zinc, ethyl zinc chloride, ethyl magnesium bromide, and the like are preferably used. As an alkoxide compound, there may be alkoxide of elements of Groups 2-14 of the long form of the periodic table such as beryllium (Be), boron (B), magnesium (Mg), aluminium (Al), silicon (Si), calcium (Ca), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), strontium (Sr), yttrium (Y), zirconium (Zr), niobium (Nb), molybdenum (Mo), technetium (Tc), ruthenium (Ru), rhodium (Rh), palladium(Pd), silver (Ag), cadmium (Cd), indium(In), tin (Sn), barium (Ba), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), hafnium (Hf), tantalum (Ta), tungsten (W), rhenium (Re), osmium (Os), iridium (Ir), platinum (Pt), gold (Au), mercury(Hg), thallium (Tl), lead (Pb), and radium (Ra).

Specific examples of an alkoxide compound may include, for example, beryllium acetylacetonate, trimethyl borate, triethyl borate, triisopropyl borate n-propyl, triisopropyl borate, tri-n-butylborate, tri-tert-butylborate, magnesium ethoxide, magnesium ethoxy ethoxide, magnesium methoxide ethoxide, magnesium acetylacetonate, aluminum trimethoxide, aluminum tri-ethoxide, aluminum tri-n-propoxide, aluminum tri-isopropoxide, aluminum tri-n-butoxide, aluminum tri-sec-butoxide, aluminum tri-tert-butoxide, aluminum acetylacetonate, acetoalkoxyaluminum diisopropylate, aluminum ethyl acetoacetate•diisopropylate, aluminum ethyl acetoacetate di-n-butyrate, aluminum diethyl acetoacetate mono n-butyrate, aluminum diisopropylate mono sec-butylate, aluminum trisacetylacetonate, aluminum trisethylacetoacetate, bis(ethylacetoacetate)(2,4-pentanedionato)aluminum, aluminum alkyl acetoacetate diisopropylate, aluminum oxide isopropoxide trimmer, aluminum oxide octylate trimmer, calcium methoxide, calcium ethoxide, calcium isopropoxide, calcium acetylacetonate, scandium acetylacetonate, titanium tetramethoxide, titanium tetraethoxide, titanium tetra-n-propoxide, titanium tetraisopropoxide, titanium tetra-n-butoxide, titanium tetraisobutoxide, titanium diisopropoxy di-n-butoxide, titanium ditertiary butoxy diisopropoxide, titanium tetra-tert-butoxide, titanium tetra-iso-octyloxide, titanium tetrastearyl alkoxide, vanadium triisobutoxide oxide, tris(2,4-pentanedionato)chromium, chromium n-propoxide, chromium isopropoxide, manganese methoxide, tris(2,4-pentanedionato)manganese, iron methoxide, iron ethoxide, iron n-propoxide, iron isopropoxide, tris(2,4-pentanedionato)iron, cobalt isopropoxide, tris(2,4-pentanedionato)cobalt, nickel acetylacetonate, copper methoxide, copper ethoxide, copper isopropoxide, copper acetylacetonate, zinc ethoxide, zinc ethoxy ethoxide, zinc methoxyethoxide, gallium methoxide, gallium ethoxide, gallium isopropoxide, gallium acetylacetonate, germanium methoxide, germanium ethoxide, germanium isopropoxide, gallium acetylacetonate, germanium methoxide, germanium ethoxide, germanium isopropoxide, germanium n-butoxide, germanium tert-butoxide, ethyl triethoxy germanium, strontium isopropoxide, yttrium n-propoxide, yttrium isopropoxide, yttrium acetylacetonate, zirconium ethoxide, zirconium n-propoxide, zirconium isopropoxide, zirconium butoxide, zirconium tert-butoxide, tetrakis(2,4-pentanedionato)zirconium, niobium ethoxide, niobium n-butoxide, niobium tert-butoxide, molybdenum ethoxide, molybdenum acetylacetonate, palladium acetylacetonate, silver acetylacetonate, cadmium acetylacetonate, tris(2,4-pentanedionato)indium, indium isopropoxide,indiumisopropoxide,indiumn-butoxide, indium methoxy ethoxide, tin n-butoxide, tin tert-butoxide, tin acetylacetonate, barium diisopropoxide, barium tert-butoxide, barium acetyl acetonate, lanthanum isopropoxide, lanthanum methoxyethoxide, lanthanum acetylacetonate, cerium n-butoxide, cerium tert-butoxide, cerium acetylacetonate, praseodymium methoxyethoxide, praseodymium acetylacetonate, neodymium methoxyethoxide, neodymium acetylacetonate, neodymium methoxyethoxide, samarium isopropoxide, samarium acetylacetonate, europium acetylacetonate, gadolinium acetyl acetonates, terbium acetylacetonate, holmium acetylacetonate, ytterbium acetylacetonate, lutetium acetylacetonate, hafnium ethoxide, hafnium n-butoxide, hafnium tert-butoxide, hafnium acetylacetonate, tantalum methoxide, tantalum ethoxide, tantalum n-butoxide, tantalum butoxide, tantalum tetramethoxide acetylacetonate, tungsten ethoxide, iridium acetylacetonate, iridium dicarbonyl acetylacetonate, thallium ethoxide, thallium acetylacetonate, and lead acetylacetonate.

In addition, the alkoxide compound having an acetylacetonate group is also preferred. The acetylacetonate group has the interaction with the central element of an alkoxide compound by a carbonyl structure, and thus, the handling property thereof becomes easy, which is preferred. In addition, preferably, the compound having a plurality of the alkoxide groups or acetylacetonate groups is more preferred from the viewpoint of reactivity or film composition.

In addition, as a central element of alkoxide, the element that easily forms coordinate bonds with a nitrogen atom in the polysilazane is preferred, and aluminum (Al), iron (Fe), or boron(B) having high Lewis acidity is more preferred.

As more preferred alkoxide compound, specifically, there may be triisopropyl borate, aluminum tri-sec-butoxide, aluminum ethyl acetoacetate diisopropylate, calcium isopropoxide, titanium tetraisopropoxide, gallium isopropoxide, aluminum diisopropylate mono sec-butylate, aluminum ethyl acetoacetate di-n-butyrate, or aluminum diethyl acetoacetate mono n-butyrate.

As an alkoxide compound, the commercially available products may be used or synthetic products may be used. Specific examples of commercially available product may include, for example, AMD (aluminum diisopropylate mono sec-butylate), ASBD (aluminum secondary butylate), ALCH (aluminum ethyl acetoacetate•diisopropylate), ALCH-TR (aluminum tris ethylacetoacetate), Alumichelate M (aluminum alkyl acetoacetate•diisopropylate), Alumichelate D (aluminum bisethylacetoacetate•monoacetylacetonate), Alumichelate A (W) (aluminum trisacetylacetonate) (the above products manufactured by Kawaken Fine Chemicals Co., Ltd.), PLENACT (Registered Trademark) AL-M (acetoalkoxyaluminum diisopropylate manufactured by Ajinomoto Fine-Techno Co., Inc.), Orgatics series (manufactured by Matsumoto Fine Chemical Co. Ltd.), and the like.

In addition, in the case of using an alkoxide compound, it is preferable to mix the compound with the solution including polysilazane under an inert gas atmosphere to suppress the intense oxidation progression, which is caused by the reaction of the alkoxide compound with water or oxygen in the air.

(Coating Solution for Forming Second Barrier Layer)

A solvent for preparing a coating solution for forming a second barrier layer is not particularly limited as long as it can dissolve the polysilazane and added compound. However, an organic solvent that does not include water and a reactive group (for example, a hydroxyl group, an amine group, and the like), which easily react with polysilazane, and is inert to polysilazane is preferred, and an aprotic organic solvent is more preferred. In detail, as a solvent, there may be an aprotic solvent; a hydrocarbon solvent such as aliphatic hydrocarbon, alicyclic hydrocarbon, and aromatic hydrocarbon, for example, pentane, hexane, cyclohexane, toluene, xylene, solvesso, and turpentine; a halogen hydrocarbon solvent such as methylene dichloride and trichloromethane; esters such as ethyl acetate and butyl acetate; ketones such as acetone and methyl ethyl ketone; ethers such as alicyclic ether and aliphatic ether such as dibutyl ether, dioxane, and tetrahydrofuran; for example, tetrahydrofuran, dibutyl ether, and mono- and polyalkylene glycol dialkyl ether(diglymes); and the like. These solvents may be used singly or as a mixture form in combination of two or more types thereof.

The concentration of polysilazane in the coating solution for forming a second barrier layer is not particularly limited, and depends on the film thickness of a layer or the pot life of the coating solution. However, it is preferably 1 to 80% by weight, more preferably 5 to 50% by weight, and still more preferably 10 to 40% by weight.

The used amount of an added compound in the coating solution for forming a second barrier layer is preferably 0.01 to 10 times and more preferably 0.06 to 6 times to the solid weight of polysilazane. When the amount represents the mole ratio of added element to the silicon atoms constituting polysilazane, the added element may be used to be preferably in the range of 1 mol % to 30 mol % and more preferably in the range of 5 mol % to 20 mol % with respect to 1 mole of silicon atom. Within the above range, it is possible to effectively obtain the second barrier layer according to the present invention.

The coating solution for forming a second barrier layer preferably includes a catalyst in order to promote the conversion. As a catalyst capable of being applied for the present invention, a basic catalyst is preferred, and especially, there may be amine catalysts such as N,N-diethyl ethanolamine, N,N-dimethyl ethanolamine, triethanolamine, triethylamine, 3-morpholinopropylamine, N,N,N′,N′-tetramethyl-1,3-diaminopropane, and N,N,N′,N′-tetramethyl-1,6-diaminohexane, metal catalysts, for example, Pt compounds such as Pt acetylacetonate, Pd compounds such as propionic acid Pd, and Rh compounds such as Rh acetylacetonate, and N-heterocyclic compounds. Among them, amine catalysts are preferably used. At this time, the concentration of catalyst added is preferably in the range of 0.1 to 10% by weight, and more preferably in the range of 0.5 to 7% by weight, with respect to the silicon compound. By setting the added amount of a catalyst in the above-described range, it is possible to avoid excess silanol formation, the decrease in a film density, the increase in a film defect, by rapid progress of a reaction and the like.

For the coating solution for forming a second barrier layer, if necessary, the additives to be listed below as an example maybe used. Examples thereof may include cellulose ethers and cellulose esters; natural resins such as ethyl cellulose, nitrocellulose, cellulose acetate, and cellulose acetate butyrate, for example; synthetic resins such as a rubber and a rosin resin, for example; condensation resins such as polymerization reins, for example; aminoplast, especially, particularly, a urea resin, a melamine formaldehyde resin, an alkyd resin, an acrylic resin, polyester or modified polyester, epoxide, polyisocyanate or blocked polyisocyanate, polysiloxane, and the like.

(Method for Applying Coating Solution for Forming Second Barrier Layer)

As a method for applying a coating solution for forming a second barrier layer, the conventionally known proper wet applying method may be employed. Specific examples thereof may include a spin coating method, a roll coating method, a flow coating method, an inkjet method, a spray coating method, a printing method, a dip-coating method, a flexible film-forming method, a bar-coating method, a gravure printing method, and the like.

The applying thickness may be properly determined according to the objects. For example, for the applying thickness per one layer of a second barrier layer, the thickness after drying is preferably about 1 nm to 10 μm, more preferably 10 nm to 1 μm, and still more preferably 20 to 500 nm. When the film thickness is 1 nm or more, it is possible to obtain sufficient barrier properties, and when it is 10 μm or less, it is possible to obtain stable coating properties at the time of forming a layer, and also, it is possible to implement high light transmittance.

The drying method, drying temperature, drying time, and drying atmosphere of the coating film after applying the coating solution are the same as the contents described in the above-described paragraph, “the first barrier layer”, and thus, the description about this will not be provided.

In addition, a method for removing water from the coating film obtained by applying the coating solution for forming a second barrier layer is the same as the content described in the above-described paragraph, “the first barrier layer”, and thus, the description about this will not be provided.

As a preferred method of performing the conversion treatment of the coating film (second coating film) obtained, the method is preferred, which includes evaporating and removing the solvent included in the coating film, and then, performing the conversion treatment through irradiating with active energy rays such as UV rays, electron beams, X-rays, α-rays, β-rays, γ-rays, and neutron rays. Among the conversion treatments by irradiating with active energy rays, the irradiation treatment by UV rays (particularly, vacuum UV rays) is preferred. The specific embodiment of this preferred conversion treatment is the same as the content described in the above-described paragraphs, (UV rays irradiation treatment) and (Vacuum UV ray irradiation treatment: excimer irradiation treatment) of “first barrier layer” and thus, the description about this will not be provided here. In addition, the conversion treatment of the coating film for forming the second barrier layer is preferably the vacuum UV ray (excimer) irradiation treatment.

In addition, for the vacuum UV ray irradiation process, the intensity illuminate of vacuum UV rays on the surface of the coating film formed with the coating solution for forming the second barrier layer is preferably 1 mW/cm² to 10 W/cm², more preferably 30 mW/cm² to 200 mW/cm², and still more preferably 50 mW/cm² to 160 mW/cm². When it is less than 1 mW/cm², there is a concern that the conversion efficiency is greatly reduced. When it exceeds 10 W/cm², there is a concern that the ablation on a coating film may occur or a substrate may be damaged.

In addition, the irradiation energy amount (irradiation dose) of vacuum UV rays on the surface of the coating film formed with the coating solution for forming a second barrier layer is preferably 10 to 10000 mJ/cm², more preferably 100 to 8000 mJ/cm², and still more preferably 200 to 6000 mJ/cm². When it is 10 mJ/cm² or more, it is possible to perform sufficient conversion. When it is 10000 mJ/cm² or less, the cracks and the deformation of a substrate generated by excess conversion are reduced.

In addition, the conversion method of the coating film for forming the second barrier layer is not limited to the above-described UV ray irradiation treatment, and for example, the conversion treatments by the heating treatment at 40° C. or higher, the heating treatment by infrared rays, the wet heat treatment of 40 to 80% or more, the oxidation treatment by oxygen, and the electron beam treatment may be equally used.

The above-described second barrier layer may be a single layer or may have the structure of laminating two or more layers. At this time, when the second barrier layer has the structure of laminating two or more layers, the respective second barrier layers may have the same composition or different composition from each other, as long as they have the above-mentioned features.

[Intermediate Layer]

The gas barrier film of the present invention may have an intermediate layer between the first barrier layer and the second barrier layer with the purpose of stress relaxation. As a method for forming such an intermediate layer, a method for forming a polysiloxane converted layer may be applied. This method is the method for forming an intermediate layer by applying a coating solution including polysiloxane with a wet applying method on a first barrier layer, drying the coating solution applied, and then, irradiating the coating film obtained through drying with vacuum UV rays.

The coating solution used for forming an intermediate layer preferably includes polysiloxane and an organic solvent.

The polysiloxane that can be applied for forming an intermediate layer is not particularly limited, but the organopolysiloxane represented by the following General Formula (6) is particularly preferred.

In the present embodiment, the organopolysiloxane represented by the following General Formula (IV) will be described as an example of the polysiloxane.

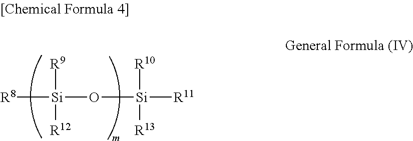

In the above General Formula (IV), R⁸ to R¹³ each independently represent an organic group having 1 to 8 carbon atoms, and at this time, at least one of R⁸ to R¹³ represents an alkoxy group or a hydroxyl group and m represents an integer of 1 or more.

Examples of an organic group having 1 to 8 carbon atoms represented by R⁸ to R¹³ may include, for example, halogenated alkyl groups such as a γ-chloropropyl group and a 3,3,3-trifluoropropyl group, a vinyl group, a phenyl group, a (meth)acrylic acid ester group such as a γ-methacryloxypropyl group, an epoxy-containing alkyl group such as a γ-glycidoxypropyl group, a mercapto-containing alkyl group such as a γ-mercapto propyl group, an aminoalkyl group such as a γ-aminopropyl group, an isocyanate-containing alkyl group such as a γ-isocyanate propyl group, an linear or branched alkyl group such as a methyl group, an ethyl group, a n-propyl group, and an isopropyl group, an alicyclic alkyl group such as a cyclohexyl group and a cyclopentyl group, a linear or branched alkoxy group such as a methoxy group, an ethoxy group, a n-propoxy group, and an isopropoxy group, an acyl group such as an acetyl group, a propionyl group, a butyryl group, a valeryl group, and a caproyl group, a hydroxyl group, and the like.

The organopolysiloxane, in which in the above-described General Formula (6), m represents 1 or more, and also, the weight average molecular weight in terms of polystyrene is 1,000 to 20,000, is particularly preferred. When the weight average molecular weight of the organopolysiloxane in terms of polystyrene is 1,000 or more, it is difficult to generate cracks in the protective layer to be formed, and it is possible to maintain vapor barrier properties. When it is 20,000 or less, the curing of the intermediate layer formed is sufficiently performed, and thus, it is possible to obtain sufficient hardness as the protective layer thus obtained.

In addition, as an organic solvent that can be applied for forming an intermediate layer, there may be an alcohol-based solvent, a ketone-based solvent, an amide-based solvent, an ester-based solvent, an aprotic solvent, and the like.

As an organic solvent used for forming an intermediate layer, the alcohol-based solvent among the above-described organic solvents is preferred.

As a method for applying the coating solution for forming an intermediate layer, there may be a spin coating method, a dipping method, a roller blade method, a spray method, and the like.

The thickness of the intermediate layer formed by the coating solution for forming an intermediate layer is preferably in the range of 100 nm to 10 μm. When the thickness of the intermediate layer is 100 nm or more, it is possible to secure the gas barrier properties under a high temperature and high humidity. In addition, when the thickness of the intermediate layer is 10 μm or less, it is possible to obtain stable coating properties at the time of forming an intermediate layer, and also, it is possible to realize high light transmittance.

In addition, the film density of the intermediate layer is generally 0.35 to 1.2 g/cm³, preferably 0.4 to 1.1 g/cm³, and more preferably 0.5 to 1.0 g/cm³. When the film density is 0.35 g/cm³ or more, it is possible to obtain the sufficient mechanical strength of a coating film.

The intermediate layer in the present invention is formed by applying the coating solution including polysiloxane through a wet applying method on a first barrier layer, drying the coating solution applied, and then, irradiating the dried coating film (polysiloxane coating film) with vacuum UV rays.

As the vacuum UV rays used for forming the intermediate layer, the vacuum UV rays used for the vacuum UV ray irradiation treatment, which is the same as described for forming the above-described barrier layer, may be employed.

[Protective Layer]

The gas barrier film according to the present invention may have a protective layer including an organic compound on the upper part of the outermost barrier layer. As an organic compound used for the protective layer, an organic-inorganic composite resin layer using an organic resin such as an organic monomer, an oligomer, and a polymer, monomers, oligomers, and polymers of siloxane or silsesquioxane having an organic group, and the like may be preferably used. These organic resins or organic-inorganic composite resins have preferably a polymerizable group or crosslinking group. It is preferable to cure the layer, which is formed by applying the organic resin composition coating solution including these organic resins or organic-inorganic composite resins and if necessary, a polymerization initiator or crosslinking agent, by adding a light irradiation treatment or heating treatment. Here, “the crosslinking group” is a group capable of crosslinking a binder polymer by the chemical reaction generated by the light irradiation treatment or heating treatment. The chemical structure thereof is not particularly limited as long as it has such a function, but for example, there may be an ethylenically unsaturated group as a functional group capable of performing the addition polymerization, and cyclic ether groups such as an epoxy group/oxetanyl group. It may be a functional group capable of forming a radical by the light irradiation, and examples of this crosslinking group may include a thiol group, a halogen atom, an onium salt structure, and the like. Among them, the ethylenically unsaturated group is preferred, and the functional groups disclosed in paragraphs [0130] to [0139] of JP 2007-17948 A are included.

The protective layer may include an inorganic material. The inorganic material is included, which leads to increasing the elastic modulus of a protective layer, generally. The elastic modulus of a protective layer may be adjusted to have the desired value by properly adjusting the inorganic material-containing ratio.

As an inorganic material, the inorganic fine particles having the number average particle diameter of 1 to 200 nm are preferred, and the inorganic fine particles having the number average particle diameter of 3 to 100 nm are more preferred. As the inorganic fine particles, the metal oxides are preferred from the viewpoint of transparency.

In order to obtain the dispersion of the inorganic fine particles, the dispersion may be prepared by the known technique, but the commercially available dispersion of inorganic fine particles may be preferably used.

In addition, the protective layer may be cured by irradiating the layer with the above-described excimer lamp. When the barrier layer and protective layer are coating-formed in the same line, the curing of the protective layer may be also preferably performed by irradiating the layer with the excimer lamp.

Furthermore, when before the conversion treatment of the outermost barrier layer, an alkoxy-modified polysiloxane coating film is formed on the coating film obtained by the coating solution for forming the outermost barrier layer, and then, the film is irradiated with vacuum UV rays, the alkoxy-modified polysiloxane coating film becomes a protective layer, and also, the conversion of the underlying coating film may be performed. Therefore, the second barrier layer having excellent gas barrier capabilities and durability thereof may be obtained.

In addition, as a method for forming a protective layer, the forming method using the polysiloxane of the intermediate layer as described above may be applied.

[Desiccant Layer]

The gas barrier film of the present invention may have a desiccant layer (water adsorption layer). Examples of materials used for the desiccant layer may include calcium oxide, organic metal oxides, and the like. The calcium oxide is preferably dispersed in a binder resin, and the like, and as commercially available products, for example, AqvaDry series manufactured by SAES Getter Corp. may be preferably used. In addition, as organic metal oxides, OleDry (Registered Trademark) series manufactured by Futaba Corp. may be used.

[Smoothing Layer (Basal Layer and Primer Layer)]

The gas barrier film of the present invention may have a smoothing layer (basal layer and primer layer) on the surface having the barrier layer of a substrate, and preferably, between the substrate and the barrier layer adjacent to the substrate. The smoothing layer is installed in order to perform the planarization of a rough surface of a substrate with projections or the planarization of a substrate by filling the unevenness parts and pinholes produced on a barrier layer with the projections present on the substrate. The smoothing layer may be formed with any kinds of materials, but preferably includes a carbon-containing polymer, and more preferably is constituted of a carbon-containing polymer. In other words, preferably, the gas barrier film of the present invention further includes the smoothing layer including a carbon-containing polymer between a substrate and a first barrier layer.

In addition, the smoothing layer may include a carbon-containing polymer, and preferably, a curable resin. The curable resin is not particularly limited, and there may be an active energy ray-curable resin obtained by irradiating an active energy ray-curable material with active energy ray such as UV rays, and then, curing the material, or a thermosetting resin obtained by heating a thermosetting material, and then, curing the material. The curable resin may be used singly, or in combination of two or more types thereof.

Examples of the active energy ray-curable material that is used for forming a smoothing layer may include an acrylate compound-containing composition, the composition including an acrylate compound and a thiol group-containing mercapto compound, the composition including multifunctional acrylate monomers such as epoxy acrylate, urethane acrylate, polyester acrylate, polyether acrylate, polyethylene glycol acrylate, and glycerol methacrylate, and the like. In detail, the organic/inorganic hybrid hard coat materials, OPSTAR (Registered Trademark) series (the compounds that are constituted of binding the silica fine particles with an organic compound having a polymeric unsaturated group) manufactured by JSR Corp., which is a UV rays curable material, may be used. In addition, any mixture of the above-described compositions may be used, and it is not particularly limited as long as it is an active energy ray-curable material including the reactive monomer having one or more photo-polymeric unsaturated bonds in the molecule.

As the reactive monomer having one or more photo-polymeric unsaturated bonds in the molecule, there may be methyl acrylate, ethyl acrylate, n-propyl acrylate, isopropyl acrylate, n-butyl acrylate, isobutyl acrylate, tert-butyl acrylate, n-pentyl acrylate, n-hexyl acrylate, 2-ethylhexyl acrylate, n-octyl acrylate, n-decyl acrylate, hydroxyethyl acrylate, hydroxypropyl acrylate, allylacrylate, benzyl acrylate, butoxyethyl acrylate, butoxyethylene glycol acrylate, cyclohexyl acrylate, dicyclopentanyl acrylate, 2-ethylhexyl acrylate, glycerol acrylate, glycidyl acrylate, 2-hydroxyethyl acrylate, 2-hydroxypropyl acrylate, isobornyl acrylate, isodecyl acrylate,isooctylacrylate,laurylacrylate,2-methoxyethyl acrylate, methoxyethyleneglycol acrylate, phenoxyethyl acrylate, stearyl acrylate, ethyleneglycol diacrylate, diethyleneglycol diacrylate, 1,4-butanediol diacrylate, 1,5-pentanediol diacrylate, 1,6-hexandiol diacrylate, 1,3-propanediol acrylate, 1,4-cyclohexanediol diacrylate, 2,2-dimethylolpropane diacrylate, glycerol diacrylate, tripropyleneglycol diacrylate, glycerol triacrylate, trimethylolpropane triacrylate, polyoxyethyl trimethylolpropane triacrylate, pentaerythritol triacrylate, pentaerythritol tetraacrylate, ethylene oxide-modified pentaerythritol triacrylate, ethylene oxide-modified pentaerythritol tetraacrylate, propylene oxide-modified pentaerythritol triacrylate, propylene triethyleneglycol diacrylate, polyoxypropyltrimethylolpropane triacrylate, butyleneglycol diacrylate, 1,2,4-butanediol triacrylate, 2,2,4-trimethyl-1,3-pentanediol diacrylate, diallyl fumarate, 1,10-decanedioldimethyl acrylate, pentaerythritol hexaacrylate, and those with methacrylates instead of the above-described acrylates, 7-methacryloxypropyltrimethoxysilane, 1-vinyl-2-pyrrolidone, and the like. These reactive monomers maybe used in the type of the mixture of one or two or more types thereof, or in the type of the mixture with other compounds.

The composition including active energy ray-curable material preferably includes a photo-polymerization initiator.

Examples of the photo-polymerization initiator may include benzophenone, methyl o-benzoyl benzoate, 4,4-bis(dimethylamine)benzophenone, 4,4-bis(diethylamine)benzophenone, α-amino-acetophenone, 4,4-dichloro-benzophenone, 4-benzoyl-4-methyl diphenyl ketone, dibenzyl ketone, fluorenone, 2,2-diethoxy acetophenone, 2,2-dimethoxy-2-phenyl acetophenone, 2-hydroxy-2-methyl propiophenone, p-tert-butyl dichloro acetophenone, thioxanthone, 2-methyl thioxanthone, 2-chlorothioxanthone, 2-isopropyl thioxanthone, diethyl thioxanthone, benzyldimethyl ketal, benzylmethoxyethyl acetal, benzoinmethyl ether, benzoinbutyl ether, anthraquinone, 2-tert-butyl-anthraquinone, 2-amyl anthraquinone, β-chloroanthraquinone, anthrone, benzanthrone, dibenzosuberone, methylene anthrone, 4-azidobenzyl acetophenone, 2,6-bis(p-azidobenzylidene)cyclohexane, 2,6-bis(p-azidobenzylidene)-4-methyl cyclohexanone, 2-phenyl-1,2-butadione 2-(o-methoxycarbonyl)oxime, 1-phenyl-propanedione-2-(o-ethoxycarbonyl)oxime, 1,3-diphenyl-propanetrione 2-(o-ethoxycarbonyl)oxime, 1-phenyl-3-ethoxy-propanetrione-2-(o-benzoyl)oxime, Michler's Ketone, 2-methyl[4-(methylthio)phenyl]-2-monopholino-1-propane, 2-benzyl-2-dimethylamino-1-(4-monopholinophenyl)-butanone-1, naphthalenesulfonyl chloride, quinoline sulfonyl chloride, n-phenylthioacridone, 4,4-azobis isobutyronitrile, diphenyl disulfide, benzothiazole disulfide, triphenylphosphine, camphor quinone, carbon tetrabromide, tribromophenylsulfone, peroxide benzoin, eosin, the combination of a photo-reducing dye such as methylene blue, and a reducing agent such as an ascorbic acid and triethanolamine, and the like. These photo-polymerization initiators may be used in combination of one or two or more types thereof.

In detail, as the thermosetting material, there may be Tutto prom series (organic polysilazane) manufactured by Clariant K.K., SP COAT heat resistance clear coating materials manufactured by Ceramic Coat Co., Ltd., Nano hybrid silicone manufactured by ADEKA Corp., UNIDIC (Registered Trademark) V-8000 series manufactured by DIC Corp., EPICLON (Registered Trademark) EXA-4710 (Super high heat-resistant epoxy resin), Silicone resin X-12-2400 (Trade Name) manufactured by Shin-Etsu Chemical Co., Ltd., Inorganic Organic nanocomposite material SSG coat manufactured by Nitto Boseki Co., Ltd., thermosetting urethane resin, phenol resin, which are constituted of acrylic polyol and isocyanate prepolymer, urea melamine resin, epoxy resin, unsaturated polyester resin, silicone resin, polyamideamine epichlorohydrin resin, and the like.

A method for forming a smoothing layer is not particularly limited, and preferably, there may be a method for forming a coating film, which includes forming the coating film by applying the coating solution including curable materials with a wet-coating method such as a spin coating method, a spray method, a blade coating method, a dipping method, and a gravure printing method, or a dry coating method such as a vapor deposition method, and then, curing the coating film by irritating with active energy ray such as visible ray, infrared ray, UV ray, X-ray, α-ray, β-ray, γ-ray, and electron ray and/or heating. As a method for irradiating with active energy rays, for example, there may be a method for irradiating with the UV rays having the wavelength region of preferably 100 to 400 nm and more preferably 200 to 400 nm using an ultra-high pressure mercury lamp, a high pressure mercury lamp, a low pressure mercury lamp, carbon arc, a metal halide lamp, and the like. In addition, there may be a method for irradiating with electron beam having the wavelength region of 100 nm or less that is emitted from a scanning-type or curtain-type electron beam accelerator.

As a solvent used for forming a smoothing layer using the coating solution prepared by dissolving or dispersing curable materials in a solvent, there may be alcohols such as methanol, ethanol, n-propyl alcohol, isopropyl alcohol, ethylene glycol, and propylene glycol, terpenes such as α- or β-terpineol, ketones such as acetone, methyl ethyl ketone, cyclohexanone, N-methyl-2-pyrrolidone, diethyl ketone, 2-heptanone, and 4-heptanone, aromatic hydrocarbons such as toluene, xylene, and tetramethyl benzene, glycol ethers such as cellosolve, methyl cellosolve, ethyl cellosolve, carbitol, methyl carbitol, ethyl carbitol, butyl carbitol, propylene glycol monomethyl ether, propylene glycol monoethyl ether, dipropylene glycol monomethyl ether, dipropylene glycol monoethyl ether, triethylene glycol monomethyl ether, and triethylene glycol monoethyl ether, acetic acid esters such as ethyl acetate, butyl acetate, cellosolve acetate, ethyl cellosolve acetate, butyl cellosolve acetate, carbitol acetate, ethyl carbitol acetate, butyl carbitol acetate, propylene glycol monomethyl ether acetate, propylene glycol monoethyl ether acetate, 2-methoxy ethyl acetate, cyclohexyl acetate, 2-ethoxy ethyl acetate, and 3-methoxybutyl acetate, diethylene glycol dialkyl ether, dipropylene glycol dialkyl ether, ethyl 3-ethoxypropionate, methyl benzoate, N,N-dimethylacetamide, N,N-dimethylformamide, and the like.

In addition to the above-described materials, the smoothing layer may include, if necessary, additives such as a thermoplastic resin, an antioxidant, an UV absorber, and a plasticizer. In addition, suitable resins or additives may be used in order to improve film-forming properties and prevent the generation of pinholes on a film. As a thermoplastic resin, there may be cellulose derivatives such as acetyl cellulose, nitrocellulose, acetyl butyl cellulose, ethyl cellulose, and methyl cellulose, vinyl resins such as vinyl acetate and a copolymer thereof, vinyl chloride and a copolymer thereof, and vinylidene chloride and a copolymer thereof, acetal resins such as polyvinyl formal, and polyvinyl butyral, acrylic resins such as an acrylic resin and a copolymer thereof, and a methacrylic resin and a copolymer thereof, a polystyrene resin, a polyamide resin, a linear polyester resin, a polycarbonate resin, and the like.

The smoothness of a smoothing layer is a value represented by the surface roughness defined in JIS B 0601: 2001, and the maximum cross-sectional height Rt (p) thereof is preferably 10 nm or more and 30 nm or less.

The surface roughness is calculated from the cross-sectional curve of the unevenness that is continuously measured with a detector having the sensing pin of a tiny tip radius in AFM (atomic force microscope), and the section is measured several times in the section of a dozen μm by the sensing pin of a tiny tip radius, and is the roughness concerning a fine unevenness amplitude.

The film thickness of the smoothing layer is not particularly limited, but preferably in the range of 0.1 to 10 μm.

[Anchor Coat Layer]

The surface of the substrate according to the present invention may include an anchor coat layer as an easily-adhesive layer for improving adhesive (coherency). As the anchor coat material that is used for the anchor coat layer, one or two or more of a polyester resin, an isocyanate resin, a urethane resin, an acrylic resin, an ethylene-vinyl alcohol resin, a vinyl-modified resin, an epoxy resin, a modified styrene resin, a modified silicone resin, and an alkyl titanate maybe used. As the anchor coat material, the materials on the market may be used. In detail, a siloxane-based UV curable polymer solution (manufactured by Shin-Etsu Chemical Co., Ltd, 3% isopropyl alcohol solution of “X-12-2400”) may be used.

These anchor coat materials may include conventionally known additives. In addition, the anchor coat materials may be coated by coating it on a substrate through a known method such as a roll coating, gravure coating, knife coating, dip-coating, and spray coating, and then, drying and removing solvents, diluents, and the like. The amount of the anchor coat material applied is preferably about 0.1 to 5 g/m² (dried state). In addition, a commercially available substrate with an easily-adhesive layer may be used.

In addition, the anchor coat layer may be formed by a vapor-phase method such as a physical vapor deposition or chemical vapor deposition method. For example, as disclosed in JP 2008-142941 A, an inorganic layer with silicon oxide as a main component may be formed with the purpose of improving adhesive properties, and the like.

In addition, the thickness of the anchor coat layer is not particularly limited, but preferably about 0.5 to 10.0 μm.

[Bleed-Out Prevention Layer]

The gas barrier film of the present invention may further have a bleed-out prevention layer. The bleed-out prevention layer is installed on the opposite side of the substrate with the smoothing layer with the purpose of suppressing the phenomenon of contaminating the side to be contacted with the shifted non-reacted oligomers and the like by shifting non-reacted oligomers and the like in the substrate when heating the film having the smoothing layer into the surface of the substrate. When the bleed-out prevention layer has such a function, the bleed-out prevention layer may have the same constitution as the smoothing layer, basically.

As the compounds that can be included in the bleed-out prevention layer, there may be a hard coat agent such as a polyunsaturated organic compound having two or more polymerizable unsaturated groups in a molecule or a monounsaturated organic compound having one polymerizable unsaturated group in a molecule.

Here, examples of the polyunsaturated organic compound may include ethylene glycol di(meth)acrylate, diethylene glycol di(meth)acrylate, glycerol di(meth)acrylate, glycerol tri(meth)acrylate, 1,4-butanediol di(meth)acrylate, 1,6-hexanediol di(meth)acrylate, neopentyl glycol di(meth)acrylate, trimethylolpropane tri(meth)acrylate, dicyclopentanyl di(meth)acrylate, pentaerythritol tri(meth)acrylate, pentaerythritol tetra(meth)acrylate, dipentaerythritolhexa(meth)acrylate, dipentaerythritol monohydroxy penta(meth)acrylate, ditrimethylolpropane tetra(meth)acrylate, diethylene glycol di(meth)acrylate, polyethylene glycol di(meth)acrylate, tripropylene glycol di(meth)acrylate, polypropylene glycol di(meth)acrylate, and the like.

In addition, examples of the monounsaturated organic compound may include methyl(meth)acrylate, ethyl(meth)acrylate, propyl(meth)acrylate, butyl(meth)acrylate, 2-ethylhexyl(meth)acrylate, isodecyl(meth)acrylate, lauryl(meth)acrylate, stearyl(meth)acrylate, allyl(meth)acrylate, cyclohexyl(meth)acrylate, methylcyclohexyl(meth)acrylate, isobornyl(meth)acrylate, 2-hydroxyethyl(meth)acrylate, 2-hydroxypropyl(meth)acrylate, glycerol(meth)acrylate, glycidyl(meth)acrylate, benzyl(meth)acrylate, 2-ethoxyethyl(meth)acrylate, 2-(2-ethoxyethoxy)ethyl(meth)acrylate, butoxyethyl(meth)acrylate, 2-methoxyethyl(meth)acrylate, methoxydiethylene glycol(meth)acrylate, methoxy triethylene glycol(meth)acrylate, methoxypolyethylene glycol(meth)acrylate, 2-methoxypropyl(meth)acrylate, methoxydipropylene glycol(meth)acrylate, methoxytripropylene glycol(meth)acrylate, methoxypolypropylene glycol(meth)acrylate, polyethylene glycol(meth)acrylate, polypropyleneglycol (meth)acrylate, and the like.

As other additives, a matting agent may be included. As a matting agent, the inorganic particles having the average particle diameter of 0.1 to 5 μm are preferred.

The above-described bleed-out prevention layer may be formed by combining a hard coat agent, and if necessary, other components, preparing the coating solution by a diluting solvent that is properly used if necessary, applying the coating solution on the surface of a substrate film by a conventionally known coating method, and curing the solution by irradiating with an ionizing radiation. In addition, a method for irradiating with an ionizing radiation includes irradiating with the UV rays having the wavelength region of preferably 100 to 400 nm and more preferably 200 to 400 nm that are emitted from an ultra-high pressure mercury lamp, a high pressure mercury lamp, a low pressure mercury lamp, carbon arc, a metal halide lamp, and the like. In addition, the method may be performed by irradiating with electron beam having the wavelength region of 100 nm or less that is emitted from a scanning-type or curtain-type electron beam accelerator.

The thickness of the bleed-out prevention layer is preferably 1 to 10 μm and more preferably 2 to 7 μm. When it is 1 μm or more, it is easy to make the heat resistance as a film sufficient. When it is 10 μm or less, it is easy to adjust the balance of the optical properties of the smoothing film, and also, it is possible to easily suppress the curling of the barrier film when the smoothing layer is installed on one side of the transparent polymer film.

<<Packaging Type of Gas Barrier Film>>

The gas barrier film of the present invention may be wound into a roll form that is continuously produced (so-called a roll-to-roll production). In this case, it is preferable to attach a protective sheet on the side having the barrier layer and to wind up. Especially, when the gas barrier film of the present invention is used as a sealing material for an organic thin film device, there are many cases that the contaminant (for example, particles) attached on the surface causes the defects, and thus, it is very effective to prevent the attachment of contaminant by attaching the protective sheet at the high cleanliness place. Furthermore, it is effective to prevent the generation of scratches, which are generated during winding, on the surface of barrier layer.

The protective sheet is not particularly limited, but a general “protective sheet” and “releasing sheet” having the constitution that imparts the low adhesive property of an adhesive layer to a resin substrate having the film thickness of about 100 μm may be used.

[Electronic Device]

The gas barrier film of the present invention may be preferably used for the device, in which the performance thereof is deteriorated by chemical components in the air (oxygen, water, nitrogen oxides, sulfur oxides, ozone, and the like). Examples of the electronic device may include, for example, electronic devices such as an organic EL element, a liquid crystal display device (LCD), a thin film transistor, a touch panel, an electronic paper, and a solar cell (PV). From the viewpoint of more effectively obtaining the effects of the present invention, it is preferably used for an organic EL element or a solar cell, and more preferably used for an organic EL device.

In addition, the gas barrier film of the present invention may be used for film-sealing of a device. In other words, using a device itself as a supporting body (substrate), the gas barrier film of the present invention is installed on the surface thereof. Before installing the gas barrier film, the device may be covered with a protective layer.

The gas barrier film of the present invention may be also used as a film for sealing by a substrate or solid sealing method of a device. A solid sealing method is a method including forming a protective layer on the device, and then, curing by overlapping an adhesive layer and gas barrier film. The adhesive is not particularly limited, but as an example, there may be a thermosetting epoxy resin, a photo-curable acrylate resin, and the like.

<Organic EL Element>

Examples of an organic EL element using a gas barrier film are disclosed in JP 2007-30387 A in detail.

<Liquid Crystal Display Device>

A reflection-type liquid crystal display device has the constitution made of, in order from the bottom, a lower substrate, a reflection electrode, a lower alignment film, a liquid crystal layer, an upper alignment film, a transparent electrode, an upper substrate, a λ/4 plate, and a polarizing film. For the present invention, the gas barrier film may be used as the above-described transparent electrode substrate and upper substrate. In the case of a color display, it is preferable to further install a color filter layer between the reflection electrode and lower alignment film or between the upper alignment film and transparent electrode. The transparent-type liquid crystal display device has the constitution made of, in order from the bottom, a backlight, a polarizing plate, a λ/4 plate, a lower transparent electrode, a lower alignment film, a liquid crystal layer, an upper alignment film, an upper transparent electrode, an upper substrate, a λ/4 plate, and a polarizing film. In the case of a color display, it is preferable to further install a color filter layer between the lower transparent electrode and lower alignment film or between the upper alignment film and transparent electrode. A type of a liquid crystal cell is not particularly limited, but more preferably a TN-type (Twisted Nematic), STN-type (Super Twisted Nematic) or HAN type (Hybrid Aligned Nematic), VA type (Vertical Alignment), ECB type (Electrically Controlled Birefringence), OCB type (Optically Compensated Bend), IPS type (In-Plane Switching), and CPA type (Continuous Pinwheel Alignment).

<Solar Cell>

The gas barrier film of the present invention may be also used for a sealing film of an organic photoelectric conversion element such as a solar cell. Here, the gas barrier film of the present invention is preferably used to seal the side close to an organic photoelectric conversion element such as a solar cell. The solar cell (organic photoelectric conversion element) that preferably uses the gas barrier film of the present invention is not particularly limited, but for example, there may be a monocrystalline silicon-based solar cell element, a polycrystalline silicon-based solar cell element, an amorphous silicon-based solar cell element constituted of a single-junction type or tandem-structure type, a semiconductor solar cell element of Group III-V compound such as gallium arsenide (GaAs) or indium phosphide (InP), a semiconductor solar cell element of Group II-VI compound such as cadmium tellurium (CdTe), a semiconductor solar cell element of Group compound such as copper/indium/selenium-based (so-called CIS-based), copper/indium/gallium/selenium-based (so-called CIGS-based), and copper/indium/gallium/selenium/sulfur-based (so-called CIGSS-based), a dye-sensitized solar cell element, an organic solar cell element, and the like. Among them, in the present invention, as the above-described solar cell element, a semiconductor solar cell element of Group compound such as copper/indium/selenium-based (so-called CIS-based), copper/indium/gallium/selenium-based (so-called CIGS-based), and copper/indium/gallium/selenium/sulfur-based (so-called CIGSS-based) is preferred.

<Others>

As other applications, there may be a thin-film transistor disclosed in JP H10-512104 W, a touch panel disclosed in JP H05-127822 Aand JP 2002-48913 A, an electronic paper disclosed in JP 2000-98326 A, and the like.

<Optical Member>

The gas barrier film of the present invention may be used as an optical member. Example of an optical member may include a circularly polarizing plate.

(Circularly Polarizing Plate)

In the present invention, the gas barrier film is used as a substrate and a λ/4 plate and a polarizing plate are laminated to prepare a circularly polarizing plate. In this case, they are laminated so as to be 45° of the angle between the slow axis of the λ/4 plate and the absorption axis of the polarizing plate. The polarizing plate that is stretched in the direction of 45° to the longitudinal direction (MD) is preferably used, and for example, the polarizing plate disclosed in JP 2002-865554 A may be suitably used.

### EXAMPLES

The effects of the present invention will be described with reference to the following Examples and Comparative Examples. However, the technical scope of the present invention is not limited only to the following Examples. In addition, in Examples, the mark of “parts” or “%” is used, and unless otherwise specified, represent “parts by mass” or “% by mass”. In addition, in the following operations, unless otherwise specified, the operations and the measurements of physical properties are performed under the conditions of a room temperature (20 to 25° C.)/relative humidity of 40 to 50%.

### Example 1

### Gas Barrier Film

<<Preparation of Gas Barrier Film>>

By the following procedures, a barrier layer (1), a barrier layer (2), and if necessary, a barrier layer (3) were formed on a substrate to prepare Gas barrier film Nos. 101 to 146. The details for the respective samples are listed in the following Table 1.

<Substrate>

As a substrate, PET film Lumirror (Registered Trademark) U34 (thickness of 100 μm) manufactured by Toray Industries, Inc.

<Barrier Layer (1)>

A barrier layer (1) was prepared by using any one of the following Formulation 1-1 to Formulation 1-8.

Formulation 1-1: (sol-gel-Si 100° C.)

A coating solution composed of 50 mol % of tetramethoxysilane, 45 mol % of 3-glycidoxypropyltrimethoxy silane, and 5 mol % of 3-aminopropyltriethoxy silane was applied on the surface of one side of a substrate at the coating speed of 2 m/min using an extrusion coater so as to have the film thickness of 1 μm after the conversion treatment; and the drying and conversion treatment were performed at 80° C. for 1 minute and 100° C. for 30 minutes to form the barrier layer (1) having the composition of SiO₂C_{0.1}. The film density measured by using XRR (M03XHF MXP3 manufactured by MAC Corp.) was 1.43 [g/cm^{3].}

Formulation 1-2: (Sol-gel-Si 130° C.)

For the Formulation 1-1, the condition of the final drying was changed into 130° C. for 30 minutes to form the barrier layer (1) having the composition of SiO₂C_{0.1}. The film density measured by using XRR was 1.53 [g/cm³].

Formulation 1-3: (Sol-gel-Si 150° C.)

For the Formulation 1-1, the condition of the final drying was changed into 150° C. for 30 minutes to form the barrier layer (1) having the composition of SiO₂C_{0.1}. The film density measured by using XRR was 1.72 [g/cm³].

Formulation 1-4: (Sol-gel-Al 130° C.)

A coating solution composed of 40 mol % of tetramethoxysilane, 12.5 mol % of tri-secondarybutoxy aluminum, 32.5 mol % of 3-glycidoxypropyltrimethoxy silane, mol % of tetrapropoxy zirconium, and 5 mol % of 3-aminopropyltriethoxy silane was applied on the surface of one side of a substrate at the coating speed of 2 m/min using an extrusion coater so as to have the film thickness of 1 pm after the conversion treatment; and the drying and conversion treatment were performed at 80° C. for 1 minute and 130° C. for 30 minutes to form the barrier layer (1) having the composition of SiAl_{0.1}O₂C_{0.1}. The film density measured by using XRR was 1.55 [g/cm³].

Formulation 1-5: (PHPS-Al d=1.95)

A polysilazane-containing coating solution prepared by mixing 4 parts by weight of a dibutyl ether solution (NN120-20 manufactured by AZ Electronic Materials Co., Ltd.) including 20% by mass of non-catalytic perhydropolysilazane, 1 part by weight of a dibutyl ether solution (NAX120-20 manufactured by AZ Electronic Materials Co., Ltd.) including 1% by mass of N,N,N′,N′-tetramethyl-1,6-diaminohexane as an amine catalyst, 19% by mass of perhydropolysilazane, and the amount of secondary butoxy diisopropoxy aluminum in an amount of 10 mol % with respect to silicon atoms, and 5 parts by weight of dibutyl ether was applied on the surface of one side of a substrate at the coating speed of 2 m/min using an extrusion coater so as to have the film thickness of 250 nm after the conversion treatment; the drying was performed at 80° C. for 1 minute; and then, irradiation was performed with the vacuum UV rays of 172 nm with the light amount of 3 J/cm² under the nitrogen atmosphere, in which the oxygen concentration was adjusted to be 0.1% to 0.01%, to form the barrier layer (1) having the composition of SiAl_{0.1}O_{2.1}. The film density measured using XRR was 1.95 [g/cm³].

Formulation 1-6: (PHPS: no excimer d=1.44)

A polysilazane-containing coating solution prepared by mixing 4 parts by weight of a dibutyl ether solution (NN120-20 manufactured by AZ Electronic Materials Co., Ltd.) including 20% by mass of non-catalytic perhydropolysilazane, 1 part by weight of a dibutyl ether solution (NAX120-20 manufactured by AZ Electronic Materials Co., Ltd.) including 1% by mass of N,N,N′,N′-tetramethyl-1,6-diaminohexane as an amine catalyst and 19% by mass of perhydropolysilazane, and 5 parts by weight of dibutyl ether was applied on the surface of one side of a substrate at the coating speed of 2 m/min using an extrusion coater so as to have the film thickness of 250 nm after the conversion treatment; the drying was performed at 80° C. for 1 minute; and then, the heating was performed under the atmosphere at 120° C. for 30 minutes to form the barrier layer (1) having the composition of SiO_{1.1}N_{0.4}. The film density measured by using XRR was 1.44 [g/cm³].

Formulation 1-7: (PHPS: excimer 3 J d=1.91)

The polysilazane-containing coating solution was applied like as Formulation 1-6; the drying was performed at 80° C. for 1 minute; and then, irradiation was performed with the vacuum UV rays of 172 nm with the light amount of 3 J/cm² under the nitrogen atmosphere, in which the oxygen concentration was adjusted to be 0.1% to 0.01%, to form the barrier layer (1) having the composition of SiO_{1.1}N_{0.4}. The film density measured by using XRR was 1.91 [g/cm³].

Formulation 1-8: (PHPS: excimer 6 J d=2.02)

For the Formulation 1-6, the irradiation light amount of vacuum UV rays was changed into 6 J to form the barrier layer (1) having the composition of SiO_{1.1}N_{0.4}. The film density measured by using XRR was 2.02 [g/cm³].

<Barrier Layer (2)>

A barrier layer (2) was prepared by using any one of the following Formulation 2-1 to Formulation 2-16.

Formulation 2-1: (Sol-gel-Si 130° C.)

A coating solution composed of 50 mol % of tetramethoxysilane, 45 mol % of 3-glycidoxypropyltrimethoxy silane, and 5 mol % of 3-aminopropyltriethoxy silane was applied on the surface of the above-prepared barrier layer (1) at the coating speed of 2 m/min using an extrusion coater so as to have the film thickness of 1 μm after the conversion treatment; and the drying and conversion treatment were performed at 80° C. for 1 minute and 130° C. for 30 minutes to form the barrier layer (2) having the composition of SiO₂C_{0.1}. The film density measured by using XRR was 1.53 [g/cm³].

Formulation 2-2 (Sol-gel-Al 130° C.)

A coating solution composed of 40 mol % of tetramethoxysilane, 12.5 mol % of tri-secondarybutoxy aluminum, 32.5 mol % of 3-glycidoxypropyltrimethoxy silane, mol % of tetrapropoxy zirconium, and 5 mol % of 3-aminopropyltriethoxy silane was applied on the surface of the above-prepared barrier layer (1) at the coating speed of 2 m/min using an extrusion coater so as to have the film thickness of 1 μm after the conversion treatment; and the drying and conversion treatment were performed at 80° C. for 1 minute and 130° C. for 30 minutes to form the barrier layer (2) having the composition of SiAl_{0.1}O₂C_{0.1}. The film density measured by using XRR was 1.55 [g/cm³].

Formulation 2-3 (PHPS)

A polysilazane-containing coating solution prepared by mixing 4 parts by weight of a dibutyl ether solution (NN120-20 manufactured by AZ Electronic Materials Co., Ltd.) including 20% by mass of non-catalytic perhydropolysilazane, 1 part by weight of a dibutyl ether solution (NAX120-20 manufactured by AZ Electronic Materials Co., Ltd.) including 1% by mass of N,N,N′,N′-tetramethyl-1,6-diaminohexane as an amine catalyst and 19% by mass of perhydropolysilazane, and 5 parts by weight of dibutyl ether was applied on the surface of the above-prepared barrier layer (1) at the coating speed of 2 m/min using an extrusion coater so as to have the film thickness of 250 nm after the conversion treatment; the drying was performed at 80° C. for 1 minute; and then, irradiation was performed with the vacuum UV rays of 172 nm with the light amount of 3 J/cm² under the nitrogen atmosphere, in which the oxygen concentration was adjusted to be 0.1% to 0.01%, to form the barrier layer (2) having the composition of SiO_{0.6}N_{0.6}. The film density measured by using XRR was 1.91 [g/cm³].

Formulation 2-4 (PHPS-Al)

The second barrier layer having the composition of SiAl_{0.1}O₂ was formed in the same method as the Formulation 2-3, except that the polysilazane-containing coating solution used for preparing the Formulation 2-3 was added with secondary butoxy diisopropoxy aluminum in an amount of 10 mol % with respect to silicon atoms, and used as a coating solution for forming a barrier layer (2) on the surface of the above-formed barrier layer (1). The film density measured by using XRR was 1.95 [g/cm³].

Formulation 2-5 (PHPS-B)

The barrier layer (2) having the composition of SiB_{0.1}O_{1.5}N_{0.3} was formed in the same method as Formulation 2-3, except that the polysilazane-containing coating solution used for preparing Formulation 2-3, which was added with trimethoxy boron so as to be 10 mol % with respect to a silicon atom, was used as a coating solution for forming a barrier layer (2) on the surface of the above-formed barrier layer (1). The film density measured using XRR was 1.90 [g/cm³].

Formulation 2-6 (PHPS-Ti)

The barrier layer (2) having the composition of SiTi_{0.1}O_{1.9}N_{0.1} was formed in the same method as the Formulation 2-3, except that the polysilazane-containing coating solution used for preparing the Formulation 2-3 was added with tetraisopropoxy titanium in an amount of 10 mol % with respect to silicon atoms, and used as a coating solution for forming a barrier layer (2) on the surface of the above-formed barrier layer (1). The film density measured by using XRR was 1.89[g/cm³].

Formulation 2-7 (PHPS-Zr)

The barrier layer (2) having the composition of SiZr_{0.1}O_{1.8}N_{0.2} was formed in the same method as the Formulation 2-3, except that the polysilazane-containing coating solution used for preparing the Formulation 2-3 was added with tetraisopropoxy zirconium in an amount of 10 mol % with respect to silicon atoms, and used as a coating solution for forming a barrier layer (2) on the surface of the above-formed barrier layer (1). The film density measured by using XRR was 1.93[g/cm³].

Formulation 2-8 (PHPS-Zn)

The barrier layer (2) having the composition of SiZn_{0.1}O_{1.8}N_{0.2} was formed in the same method as the Formulation 2-3, except that the polysilazane-containing coating solution used for preparing the Formulation 2-3 was added with diethyl zinc in an amount of 10 mol % with respect to silicon atoms, and used as a coating solution for forming a barrier layer (2) on the surface of the above-formed barrier layer (1). The film density measured by using XRR was 1.94 [g/cm³].

Formulation 2-9 (PHPS-Ge)

The barrier layer (2) having the composition of SiGe_{0.1}O_{1.5}N_{0.2} was formed in the same method as the Formulation 2-3, except that the polysilazane-containing coating solution used for preparing the Formulation 2-3 was added with tetraisopropoxy germanium in an amount of 10 mol % with respect to silicon atoms, and used as a coating solution for forming a barrier layer (2) on the surface of the above-formed barrier layer (1). The film density measured by using XRR was 1.89[g/cm³].

Formulation 2-10 (PHPS-Mg)

The barrier layer (2) having the composition of SiMg_{0.1}O_{1.5}N_{0.3} was formed in the same method as the Formulation 2-3, except that the polysilazane-containing coating solution used for preparing the Formulation 2-3 was added with 5% ethyl magnesium bromide tetrahydrofuran solution in an amount of 10 mol % with respect to silicon atoms, and used as a coating solution for forming a barrier layer (2) on the surface of the above-formed barrier layer (1). The film density measured by using XRR was 1.91 [g/cm³].

Formulation 2-11 (PHPS-Al Little 1)

The barrier layer (2) having the composition of SiAl_{0.01}O_{1.5}N_{0.5} was formed in the same method as the Formulation 2-3, except that the polysilazane-containing coating solution used for preparing the Formulation 2-3 was added with secondary butoxy diisopropoxy aluminum in an amount of 1 mol % with respect to silicon atoms, and used as a coating solution for forming a barrier layer (2) on the surface of the above-formed barrier layer (1). The film density measured by using XRR was 1.91 [g/cm³].

Formulation 2-12 (PHPS-Al Little 2)

The barrier layer (2) having the composition of SiAl_{0.05}O_{1.6}N_{0.3} was formed in the same method as the Formulation 2-3, except that the polysilazane-containing coating solution used for preparing the Formulation 2-3 was added with secondary butoxy diisopropoxy aluminum in an amount of 5 mol % with respect to silicon atoms, and used as a coating solution for forming a barrier layer (2) on the surface of the above-formed barrier layer (1). The film density measured by using XRR was 1.93 [g/cm³].

Formulation 2-13 (PHPS-Al Much 1)

The barrier layer (2) having the composition of SiAl_{0.2}O_{2.1} was formed in the same method as the Formulation 2-3, except that the polysilazane-containing coating solution used for preparing the Formulation 2-3 was added with secondary butoxy diisopropoxy aluminum in an amount of 20 mol % with respect to silicon atoms, and used as a coating solution for forming a barrier layer (2) on the surface of the above-formed barrier layer (1). The film density measured by using XRR was 1.96 [g/cm³].

Formulation 2-14 (PHPS-Al Much 2)

The barrier layer (2) having the composition of SiAl_{0.3}O_{2.2} was formed in the same method as the Formulation 2-3, except that the polysilazane-containing coating solution used for preparing the Formulation 2-3 was added with secondary butoxy diisopropoxy aluminum in an amount of 30 mol % with respect to silicon atoms, and used as a coating solution for forming a barrier layer (2) on the surface of the above-formed barrier layer (1). The film density measured by using XRR was 1.97 [g/cm³].

Formulation 2-15 (PHPS-Al/B) The barrier layer (2) having the composition of SiB_{0.05}Al_{0.1}O_{1.8}N_{0.1} was formed in the same method as the Formulation 2-3, except that the polysilazane-containing coating solution used for preparing the Formulation 2-3 was added with di-secondary butoxy isopropoxy aluminum in an amount of 10 mol % with respect to silicon atoms and trimethoxy boron in an amount of 5 mol % with respect to silicon atoms, and used as a coating solution for forming a barrier layer (2) on the surface of the above-formed barrier layer (1). The film density measured by using XRR was 1.92 [g/cm³].

Formulation 2-16 (HMePS-Al)

The barrier layer (2) having the composition of SiAl_{0.1}O₂C_{0.2} was formed in the same method as the Formulation 2-3, except that monohydro monomethyl polysilazane was used instead of perhydropolysilazane of the Formulation 2-3, on the surface of the above-formed barrier layer (1). The film density measured by using XRR was 1.87 [g/cm³].

<Barrier Layer (3)>

A barrier layer (3) was prepared by using any one of the following Formulation 3-1 and Formulation 3-2.

Formulation 3-1 (PHPS)

The polysilazane-containing coating solution prepared by mixing 4 parts by weight of a dibutyl ether solution (NN120-20 manufactured by AZ Electronic Materials Co., Ltd.) including 20% by mass of non-catalytic perhydropolysilazane, 1 part by weight of a dibutyl ether solution (NAX120-20 manufactured by AZ Electronic Materials Co., Ltd.) including 1% by mass of N,N,N′,N′-tetramethyl-1,6-diaminohexane as an amine catalyst and 19% by mass of perhydropolysilazane, and 5 parts by weight of dibutyl ether was applied on the surface of the above-prepared barrier layer (2) at the coating speed of 2 m/min using an extrusion coater so as to have the film thickness of 250 nm after the conversion treatment; the drying was performed at 80° C. for 1 minute; and then, irradiation was performed with the vacuum UV rays of 172 nm with the light amount of 3 J/cm² under the nitrogen atmosphere, in which the oxygen concentration was adjusted to be 0.1% to 0.01%, to form the barrier layer (3) having the composition of SiO_{0.6}N_{0.6}. The film density measured using XRR was 1.91 [g/cm³].

Formulation 3-2 (PHPS-Al)

The barrier layer (3) having the composition of SiAl_{0.1}O₂ was formed in the same method as the Formulation 3-1, except that the polysilazane-containing coating solution used for preparing the Formulation 3-1 was added with secondary butoxy diisopropoxy aluminum in an amount of 10 mol % with respect to silicon atoms, and used as a coating solution for forming a barrier layer (3) on the surface of the above-formed barrier layer (2). The film density measured using XRR was 1.95 [g/cm³].

<<Measurement of Composition of Gas Barrier Film>>

The composition distributions to the above-prepared Gas barrier film Nos. 101 to 146 were measured by the method using a XPS analysis according to the following analyzing conditions. In addition, when the concentration was changed in a thickness direction, the average value of the respective barrier layer (1), barrier layer (2), and barrier layer (3) in the thickness direction was used as the composition of each of the layers. The results are listed in the following Table 1.

(XPS Analyzing Condition)
Device: QUANTERASXM manufactured by ULVAC-PHI, Inc.
X ray source: Monochromatic Al-Ka
Measurement area: Si2p, C1s, N1s, O1s
Sputter ion: Ar (2 keV)
Depth profile: After sputtering for 1 minute, the measurements were repeated.
Quantitation: The background was obtained by a Shirley method, and the quantity was measured by using a relative sensitivity coefficient method from the obtained peak area. The data was treated using MultiPak manufactured by ULVAC-PHI, Inc.

<<Evaluation 1: Evaluation of WVTR>>

To the above-prepared Gas barrier film Nos. 101 to 146, WVTR was measured at 40° C. and 90% RH using a film permeable evaluation device API-BA90 manufactured by NIPPON API Co., Ltd. The results are listed in the following Table 2.

<<Evaluation 2: WVTR After Durability Test>>

The durability test of barrier film was performed as follows: while repeating the cycle including cutting each of the above-prepared Gas barrier film Nos. 101 to 146 to be a 10 cm square, winding it for 30 seconds in a 50 mφ column so as for the side of barrier layer to be inside, leaving it for 1 hour, spreading it on the plane for 30 seconds, and then, leaving it for 1 hour, the cooling cycle including cooling from 25° C. to 0° C. at the cooling rate of 10° C./hr to reach the temperature to be 0° C., then increasing it to be 70° C. at the heating rate of 10° C./hr, and then, cooling it to be 25° C. at the cooling rate of 10° C./hr was performed 100 times. Then, WVTR was measured. The results are listed in the following Table 2.

TABLE 1

| | Barrier layer (1) (Substrate) | | | | | | Barrier layer (2) | | | | | |
|---|---|---|---|---|---|---|---|---|---|---|---|---|
| | | Film | Prepa- | Compo- | | | | Film | Prepa- | Compo- | | |
| Sample | Formu- | density | ration | sition | | Added | Formu- | density | ration | sition | | Added |
| No. | lations | g/cm³ | method | O/Si | N/Si | element | lations | g/cm³ | method | O/Si | N/Si | element |
| 101 | 1-1 | 1.43 | Sol-gel-Si | 2 | 0 | — | — | | | | | |
| | | | (100° C.) | | | | | | | | | |
| 102 | 1-2 | 1.53 | Sol-gel-Si | 2 | 0 | — | — | | | | | |
| | | | (130° C.) | | | | | | | | | |
| 103 | 1-3 | 1.72 | Sol-gel-Si | 2 | 0 | — | — | | | | | |
| | | | (150° C.) | | | | | | | | | |
| 104 | 1-2 | 1.53 | Sol-gel-Si | 2 | 0 | — | 2-1 | 1.53 | Sol-gel-Si | 2 | 0 | — |
| | | | (130° C.) | | | | | | (130° C.) | | | |
| 105 | 1-2 | 1.53 | Sol-gel-Si | 2 | 0 | — | 2-2 | 1.55 | Sol-gel-Al | 2 | 0 | Al |
| | | | (130° C.) | | | | | | (130° C.) | | | |
| 106 | 1-4 | 1.55 | Sol-gel-Al | 2 | 0 | Al | 2-1 | 1.53 | Sol-gel-Si | 2 | 0 | — |
| | | | (130° C.) | | | | | | (130° C.) | | | |
| 107 | 1-4 | 1.55 | Sol-gel-Al | 2 | 0 | Al | 2-2 | 1.55 | Sol-gel-Al | 2 | 0 | (Al) |
| | | | (130° C.) | | | | | | (130° C.) | | | |
| 108 | 1-1 | 1.43 | Sol-gel-Si | 2 | 0 | — | 2-3 | 1.91 | PHPS | 0.6 | 0.6 | — |
| | | | (100° C.) | | | | | | | | | |
| 109 | 1-2 | 1.53 | Sol-gel-Si | 2 | 0 | — | 2-3 | 1.91 | PHPS | 0.6 | 0.6 | — |
| | | | (130° C.) | | | | | | | | | |
| 110 | 1-3 | 1.72 | Sol-gel-Si | 2 | 0 | — | 2-3 | 1.91 | PHPS | 0.6 | 0.6 | — |
| | | | (150° C.) | | | | | | | | | |
| 111 | 1-1 | 1.43 | Sol-gel-Si | 2 | 0 | — | 2-4 | 1.95 | PHPS—Al | 2 | 0 | Al |
| | | | (100° C.) | | | | | | | | | |
| 112 | 1-2 | 1.53 | Sol-gel-Si | 2 | 0 | — | 2-4 | 1.95 | PHPS—Al | 2 | 0 | Al |
| | | | (130° C.) | | | | | | | | | |
| 113 | 1-3 | 1.72 | Sol-gel-Si | 2 | 0 | — | 2-4 | 1.95 | PHPS—Al | 2 | 0 | Al |
| | | | (150° C.) | | | | | | | | | |
| 114 | 1-5 | 1.95 | PHPS—Al | 2.1 | 0 | Al | 2-1 | 1.53 | Sol-gel-Si | 2 | 0 | — |
| | | | | | | | | | (130° C.) | | | |
| 115 | 1-2 | 1.53 | Sol-gel-Si | 2 | 0 | — | 2-5 | 1.9 | PHPS—B | 1.5 | 0.3 | B |
| | | | (130° C.) | | | | | | | | | |
| 116 | 1-2 | 1.53 | Sol-gel-Si | 2 | 0 | — | 2-6 | 1.89 | PHPS—Ti | 1.9 | 0.1 | Ti |
| | | | (130° C.) | | | | | | | | | |
| 117 | 1-2 | 1.53 | Sol-gel-Si | 2 | 0 | — | 2-7 | 1.93 | PHPS—Zr | 2 | 0.1 | Zr |
| | | | (130° C.) | | | | | | | | | |
| 118 | 1-2 | 1.53 | Sol-gel-Si | 2 | 0 | — | 2-8 | 1.94 | PHS—Zn | 1.8 | 0.2 | Zn |
| | | | (130° C.) | | | | | | | | | |
| 119 | 1-2 | 1.53 | Sol-gel-Si | 2 | 0 | — | 2-9 | 1.89 | PHPS—Ge | 1.5 | 0.2 | Ge |
| | | | (130° C.) | | | | | | | | | |
| 120 | 1-2 | 1.53 | Sol-gel-Si | 2 | 0 | — | 2-10 | 1.91 | PHPS—Mg | 1.5 | 0.3 | Mg |
| | | | (130° C.) | | | | | | | | | |
| 121 | 1-6 | 1.44 | PHPS | 1.1 | 0.4 | — | — | | | | | |
| 122 | 1-7 | 1.91 | PHPS | 1.1 | 0.4 | — | — | | | | | |
| 123 | 1-8 | 2.02 | PHPS | 1.1 | 0.4 | — | — | | | | | |
| 124 | 1-6 | 1.44 | PHPS | 1.1 | 0.4 | — | 2-3 | 1.91 | PHPS | 0.6 | 0.6 | — |
| 125 | 1-7 | 1.91 | PHPS | 1.1 | 0.4 | — | 2-3 | 1.91 | PHPS | 0.6 | 0.6 | — |
| 126 | 1-8 | 2.02 | PHPS | 1.1 | 0.4 | — | 2-3 | 1.91 | PHPS | 0.6 | 0.6 | — |
| 127 | 1-6 | 1.44 | PHPS | 1.1 | 0.4 | — | 2-4 | 1.95 | PHPS—Al | 2 | 0 | Al |
| 128 | 1-7 | 1.91 | PHPS | 1.1 | 0.4 | — | 2-4 | 1.95 | PHPS—Al | 2 | 0 | Al |
| 129 | 1-8 | 2.02 | PHPS | 1.1 | 0.4 | — | 2-4 | 1.95 | PHPS—Al | 2 | 0 | Al |
| 130 | 1-5 | 1.95 | PHPS—Al | 2.1 | 0 | Al | 2-3 | 1.91 | PHPS | 0.6 | 0.6 | — |
| 131 | 1-7 | 1.91 | PHPS | 1.1 | 0.4 | — | 2-5 | 1.9 | PHPS—B | 1.5 | 0.3 | B |
| 132 | 1-7 | 1.91 | PHPS | 1.1 | 0.4 | — | 2-6 | 1.89 | PHPS—Ti | 1.9 | 0.1 | Ti |
| 133 | 1-7 | 1.91 | PHPS | 1.1 | 0.4 | — | 2-7 | 1.93 | PHPS—Zr | 2 | 0.1 | Zr |
| 134 | 1-7 | 1.91 | PHPS | 1.1 | 0.4 | — | 2-8 | 1.94 | PHPS—Zn | 1.8 | 0.2 | Zn |
| 135 | 1-7 | 1.91 | PHPS | 1.1 | 0.4 | — | 2-9 | 1.89 | PHPS—Ge | 1.5 | 0.2 | Ge |
| 136 | 1-7 | 1.91 | PHPS | 1.1 | 0.4 | — | 2-10 | 1.91 | PHPS—Mg | 1.5 | 0.3 | Mg |
| 137 | 1-7 | 1.91 | PHPS | 1.1 | 0.4 | — | 2-11 | 1.91 | PHPS—Al | 1.5 | 0.5 | Al |
| | | | | | | | | | (little 1) | | | |
| 138 | 1-7 | 1.91 | PHPS | 1.1 | 0.4 | — | 2-12 | 1.93 | PHPS—Al | 1.6 | 0.3 | Al |
| | | | | | | | | | (little 2) | | | |
| 139 | 1-7 | 1.91 | PHPS | 1.1 | 0.4 | — | 2-13 | 1.96 | PHPS—Al | 2.1 | 0 | Al |
| | | | | | | | | | (much 1) | | | |
| 140 | 1-7 | 1.91 | PHPS | 1.1 | 0.4 | — | 2-14 | 1.97 | PHPS—Al | 2.2 | 0 | Al |
| | | | | | | | | | (much 2) | | | |
| 141 | 1-7 | 1.91 | PHPS | 1.1 | 0.4 | — | 2-15 | 1.92 | PHPS—Al/B | 1.8 | 0.1 | Al/B |
| 142 | 1-7 | 1.91 | PHPS | 1.1 | 0.4 | — | 2-16 | 1.87 | HMePS—Al | 2 | 0 | Al |
| 143 | 1-7 | 1.91 | PHPS | 1.1 | 0.4 | — | 2-3 | 1.91 | PHPS | 0.6 | 0.6 | — |
| 144 | 1-7 | 1.91 | PHPS | 1.1 | 0.4 | — | 2-4 | 1.95 | PHPS—Al | 2 | 0 | Al |
| 145 | 1-5 | 1.95 | PHPS—Al | 2.1 | 0 | Al | 2-3 | 1.91 | PHPS | 0.6 | 0.6 | — |
| 146 | 1-5 | 1.95 | PHPS—Al | 2.1 | 0 | Al | 2-4 | 1.95 | PHPS—Al | 2 | 0 | Al |

| | Barrier layer (3) | | | | | | |
|---|---|---|---|---|---|---|---|
| | | Film | Prepa- | Compo- | | | |
| Sample | Formu- | density | ration | sition | | Added | |
| No. | lations | g/cm³ | method | O/Si | N/Si | element | Note |
| 101 | — | | | | | | Comparison |
| 102 | — | | | | | | Comparison |
| 103 | — | | | | | | Comparison |
| 104 | — | | | | | | Comparison |
| 105 | — | | | | | | Present invention A |
| 106 | — | | | | | | Present Invention B |
| 107 | — | | | | | | Present invention A/B |
| 108 | — | | | | | | Comparison |
| 109 | — | | | | | | Comparison |
| 110 | — | | | | | | Comparison |
| 111 | — | | | | | | Present invention A |
| 112 | — | | | | | | Present invention A |
| 113 | — | | | | | | Present invention A |
| 114 | — | | | | | | Present invention B |
| 115 | — | | | | | | Present invention A |
| 116 | — | | | | | | Present invention A |
| 117 | — | | | | | | Present invention A |
| 118 | — | | | | | | Present invention A |
| 119 | — | | | | | | Present invention A |
| 120 | — | | | | | | Present invention A |
| 121 | — | | | | | | Comparison |
| 122 | — | | | | | | Comparison |
| 123 | — | | | | | | Comparison |
| 124 | — | | | | | | Comparison |
| 125 | — | | | | | | Comparison |
| 126 | — | | | | | | Comparison |
| 127 | — | | | | | | Present invention A |
| 128 | — | | | | | | Present invention A |
| 129 | — | | | | | | Present invention A |
| 130 | — | | | | | | Present invention B |
| 131 | — | | | | | | Present invention A |
| 132 | — | | | | | | Present invention A |
| 133 | — | | | | | | Present invention A |
| 134 | — | | | | | | Present invention A |
| 135 | — | | | | | | Present invention A |
| 136 | — | | | | | | Present invention A |
| 137 | — | | | | | | Comparison |
| 138 | — | | | | | | Present invention A |
| 139 | — | | | | | | Present invention A |
| 140 | — | | | | | | Present invention A |
| 141 | — | | | | | | Present invention A |
| 142 | — | | | | | | Present invention A |
| 143 | 3-2 | 1.95 | PHPS—Al | 2 | 0 | Al | Present invention C |
| | | | | | | | (First-First-Second) |
| 144 | 3-2 | 1.95 | PHPS—Al | 2 | 0 | Al | Present invention C |
| | | | | | | | (First-Second-Second) |
| 145 | 3-2 | 1.95 | PHPS—Al | 2 | 0 | Al | Present invention C |
| | | | | | | | (Second-First-Second) |
| 146 | 3-1 | 1.91 | PHPS | 0.6 | 0.6 | — | Present invention C |
| | | | | | | | (Second-Second-First) |

The present invention A: the constitution including the arrangement of substrate/first barrier layer/second barrier layer

The present invention B: the constitution including the arrangement of substrate/second barrier layer/first barrier layer

The present invention C: the constitution including three or more layers of the barrier layers

TABLE 2

WVTR (40° C. 90%)

| Sample | Immediate | After | |
|---|---|---|---|
| No. | evaluation | durability test | Note |
| 101 | 1 × 10⁻² | 8 × 10⁻¹ | Comparison |
| 102 | 5 × 10⁻³ | 5 × 10⁻¹ | Comparison |
| 103 | 2 × 10⁻³ | 4 × 10⁻¹ | Comparison |
| 104 | 2 × 10⁻³ | 1 × 10⁻¹ | Comparison |
| 105 | 1 × 10⁻³ | 2 × 10⁻³ | Present invention A |
| 106 | 1 × 10⁻³ | 2 × 10⁻³ | Present invention B |
| 107 | 8 × 10⁻⁴ | 1 × 10⁻³ | Present invention A/B |
| 108 | 4 × 10⁻³ | 5 × 10⁻¹ | Comparison |
| 109 | 2 × 10⁻³ | 3 × 10⁻¹ | Comparison |
| 110 | 1 × 10⁻³ | 2 × 10⁻¹ | Comparison |
| 111 | 7 × 10⁻⁵ | 8 × 10⁻⁵ | Present invention A |
| 112 | 4 × 10⁻⁵ | 5 × 10⁻⁵ | Present invention A |
| 113 | 2 × 10⁻⁵ | 3 × 10⁻⁵ | Present invention A |
| 114 | 8 × 10⁻⁵ | 1 × 10⁻⁴ | Present invention B |
| 115 | 5 × 10⁻⁵ | 6 × 10⁻⁵ | Present invention A |
| 116 | 1 × 10⁻⁴ | 2 × 10⁻⁴ | Present invention A |
| 117 | 2 × 10⁻⁴ | 3 × 10⁻⁴ | Present invention A |
| 118 | 8 × 10⁻⁵ | 1 × 10⁻⁴ | Present invention A |
| 119 | 2 × 10⁻⁴ | 3 × 10⁻⁴ | Present invention A |
| 120 | 5 × 10⁻⁴ | 7 × 10⁻⁴ | Present invention A |
| 121 | 6 × 10⁻³ | 4 × 10⁻¹ | Comparison |
| 122 | 2 × 10⁻³ | 3 × 10⁻¹ | Comparison |
| 123 | 3 × 10⁻³ | 2 × 10⁻¹ | Comparison |
| 124 | 5 × 10⁻³ | 3 × 10⁻¹ | Comparison |
| 125 | 3 × 10⁻³ | 2 × 10⁻¹ | Comparison |
| 126 | 2 × 10⁻³ | 2 × 10⁻¹ | Comparison |
| 127 | 3 × 10⁻⁵ | 3 × 10⁻⁵ | Present invention A |
| 128 | 2 × 10⁻⁵ | 2 × 10⁻⁵ | Present invention A |
| 129 | 1 × 10⁻⁵ | 1 × 10⁻⁵ | Present invention A |
| 130 | 4 × 10⁻⁵ | 4 × 10⁻⁴ | Present invention B |
| 131 | 2 × 10⁻⁵ | 3 × 10⁻⁵ | Present invention A |
| 132 | 8 × 10⁻⁵ | 9 × 10⁻⁵ | Present invention A |
| 133 | 1 × 10⁻⁴ | 1 × 10⁻⁴ | Present invention A |
| 134 | 6 × 10⁻⁵ | 7 × 10⁻⁵ | Present invention A |
| 135 | 1 × 10⁻⁴ | 2 × 10⁻⁴ | Present invention A |
| 136 | 3 × 10⁻⁴ | 6 × 10⁻⁴ | Present invention A |
| 137 | 2 × 10⁻⁴ | 2 × 10⁻² | Comparison |
| 138 | 4 × 10⁻⁵ | 6 × 10⁻⁵ | Present invention A |
| 139 | 3 × 10⁻⁵ | 3 × 10⁻⁵ | Present invention A |
| 140 | 4 × 10⁻⁵ | 8 × 10⁻⁵ | Present invention A |
| 141 | 1 × 10⁻⁴ | 1 × 10⁻⁴ | Present invention A |
| 142 | 3 × 10⁻⁵ | 3 × 10⁻⁵ | Present invention A |
| 143 | 4 × 10⁻⁶ | 5 × 10⁻⁶ | Present invention C |
| | | | (First-First-Second) |
| 144 | 2 × 10⁻⁶ | 2 × 10⁻⁶ | Present invention C |
| | | | (First-Second-Second) |
| 145 | 3 × 10⁻⁵ | 4 × 10⁻⁵ | Present invention C |
| | | | (Second-First-Second) |
| 146 | 4 × 10⁻⁵ | 6 × 10⁻⁵ | Present invention C |
| | | | (Second-Second-First) |

From the results listed in Table 2, it could be confirmed that for the gas barrier films according to the present invention, the gas barrier capabilities were excellent in an immediate evaluation, and also, after durability test, the decreases in gas barrier capabilities were prevented (that is, the durability was excellent).

In addition, from the results exhibited in Samples Nos. 112, and 115 to 120 or the results exhibited in Samples Nos. 128, and 131 to 136, it could be confirmed that the second barrier layer including at least one type selected from the group consisting of boron (B), aluminum (Al), gallium (Ga), and indium (In) (especially by including aluminum (Al)) as an added element exhibited excellent gas barrier properties in all of the immediate evaluation and after the durability test.

In addition, from the comparison of Samples Nos. 112 and 114 and the comparison of Samples Nos. 128 and 130, it could be confirmed that the constitution of the present invention A (the constitution including the arrangement of substrate/first barrier layer/second barrier) exhibited more excellent gas barrier properties in all of the immediately evaluation and after the durability test, as compared with the constitution of the present invention B (the constitution including the arrangement of substrate/second barrier layer/first barrier layer).

In addition, in the case of the constitution of the present invention C (the constitution including three or more layers of the barrier layers), when the barrier layer that was the closest layer to the substrate was a first barrier layer, and the barrier layer that is the furthermost layer from the substrate was a second barrier layer, excellent gas barrier properties were exhibited in all of the immediate evaluation and after the durability test.

### Example 2

### OLED Device

<<Production of Electronic Device>>

An organic EL (OLED) device that was an organic thin film electronic device was manufactured in the following procedures using the gas barrier film listed in the following Table 3 as a substrate.

[Production of Organic EL Device]

(Formation of First Electrode Layer)

ITO (indium thin oxide) having the thickness of 150 nm was applied on the barrier layer of the gas barrier film to prepare a film by a sputtering method, and then, was subjected to a pattering by a photolithography method to form a first electrode layer.

(Formation of Hole Transport Layer)

The coating solution for forming a hole transport layer as described below was applied on the above-formed first electrode layer with an extrusion coater with the thickness of 50 nm after drying, and then, dried to form a hole transport layer.

Before applying the coating solution for forming a hole transport layer, the cleaning surface modification treatment of the gas barrier film was performed using a low pressure mercury lamp having the wavelength of 184.9 nm at the irradiation intensity of 15 mW/cm² and a distance of 10 mm. The electrification removing treatment was performed using an electrostatic eliminator by a weak X-ray.

<Applying Condition>

The applying process was performed under the environment of 25° C. and relative humidity of 50% RH in the air.

<Preparation of Coating Solution for Forming Hole Transport Layer>

The solution prepared by diluting Polyethylene dioxythiophene•polystyrene sulfonate (PEDOT/PSS, Baytron (Registered Trademark) PAI 4083 manufactured by Bayer Holding Ltd.) with 65% pure water and 5% methanol was prepared as a coating solution for forming a hole transport layer.

<Drying and Heating Treatment Condition>

After applying the coating solution for forming a hole transport layer, the hot air of the height of 100 mm, the ejection velocity of 1 m/s, the wind speed distribution of 5% in awidthdirection, and the temperature of 100° C. was applied to the film-forming surface, the solvent was removed, and then, subsequently, the heating treatment in a backside heat transferring way was performed at the temperature of 150° C. using a heating device to form the hole transport layer.

(Formation of Light-Emitting Layer)

Subsequently, on the above-formed hole transport layer, the coating solution for forming a white light-emitting layer as described below was applied with an extrusion coater with the thickness of 40 nm after drying, and then, dried to form a light-emitting layer.

<Coating Solution for Forming White Light-Emitting Layer>

1.0 g of a host material H-A, 100 mg of a dopant material D-A, 0.2 mg of a dopant material D-B, and 0.2 mg of a dopant material D-C were dissolved in 100 g of toluene to prepare the coating solution for forming a white light-emitting layer. The chemical structures of the host material H-A, dopant material D-A, dopant material D-B, and dopant material D-C are represented by the following Chemical Formulas.

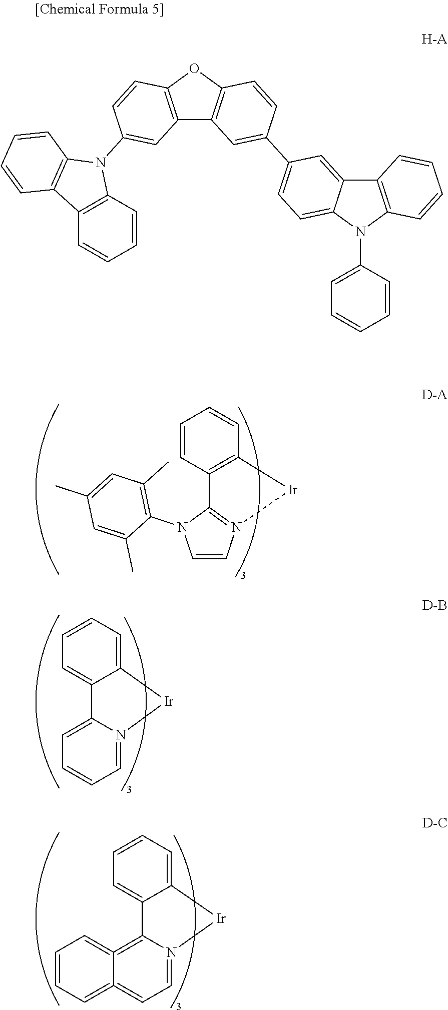

<Applying Condition>

The applying process was performed at the applying temperature of 25° C. and the applying rate of 1 m/min under the atmosphere of the nitrogen gas concentration of 99% or more.

<Drying and Heating Treatment Condition>

After applying the coating solution for forming a white light-emitting layer, the hot air of the height of 100 mm, the ejection velocity of 1 m/s, the wind speed distribution of 5% in a width direction, and the temperature of 60° C. was applied to the film-forming surface, the solvent was removed, and then, subsequently, the heating treatment was performed at the temperature of 130° C. to form the white light-emitting layer.

(Formation of Electron Transport Layer)

Subsequently, on the above-formed light-emitting layer, the coating solution for forming an electron transport layer as described below was applied with an extrusion coater with the thickness of 30 nm after drying, and then, dried to form the electron transport layer.

<Applying Condition>

The applying process was performed at the applying temperature of 25° C. and the applying rate of 1 m/min of the coating solution for forming the electron transport layer under the atmosphere of the nitrogen gas concentration of 99% or more.

<Coating Solution for Forming Electron Transport Layer>

For the electron transport layer, the solution of 0.5% by mass prepared by dissolving E-A (seethe following Chemical Formula) in 2,2,3,3-tetrafluoro-1-propanol was prepared as the coating solution for forming the electron transport layer.

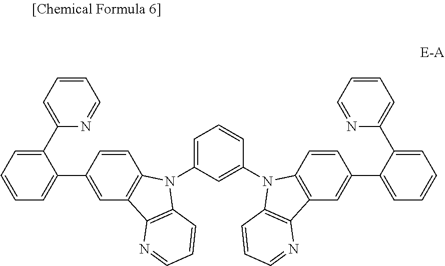 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

<Drying and Heating Treatment Condition>After applying the coating solution for forming an electron transport layer, the hot air of the height of 100 mm, the ejection velocity of 1 m/s, the wind speed distribution of 5% in a width direction, and the temperature of 60° C. was applied to the film-forming surface, the solvent was removed, and then, subsequently, the heating treatment was performed at the temperature of 200° C. in a heating unit to form the electron transport layer.

(Formation of Electron Injecting Layer)

Subsequently, an electron injecting layer was formed on the above-formed electron transport layer. First, a substrate was put into a depressurized chamber, and then, the pressure thereof was reduced to be 5×10⁻⁴ Pa. Cesium fluoride that was in advance prepared in a tantalum deposition boat in a vacuum chamber was heated to form an electron injecting layer having the thickness of 3 nm.

(Formation of Second Electrode)

Subsequently, the second electrode having the thickness of 100 nm was laminated on the above-formed electron injecting layer in a mask pattern under the vacuum of 5×10⁻⁴ Pa using aluminum as a material for forming the second electrode and a vapor deposition method so as to have an extraction electrode.

(Formation of Protective Layer)

Subsequently, with the exception of the parts to be the extraction unit of the first electrode and second electrode, SiO₂ was laminated to have the thickness of 200 nm with a CVD method to form a protective layer on the second electrode layer.

As described above, an electronic device body was produced.

[Sealing]

As a sealing member, the member prepared by dry-laminating a polyethylene terephthalate (PET) film (thickness of 12 μm) on an aluminum foil (manufactured by Toyo Aluminium K.K.) having the thickness of 30 μm using an adhesive (2-liquid reaction type urethane-based adhesive) for a dry lamination was used (the thickness of adhesive layer of 1.5 μm), and then, the sealing was performed using a sheet-typed sealing material, TB1655, manufactured by ThreeBond Holdings Co., Ltd. to prepare Samples 201 to 207.

<<Evaluation of Organic EL Device>>

To the above-produced organic EL device, the durability test was performed according to the following method. In addition, as the gas barrier film that was used as the substrate of the organic EL element, all the films that were immediately evaluated and were after durability test as described above were used.

(Accelerated Deterioration Treatment)

Each of the above-produced organic EL devices was subjected to the accelerated deterioration treatment under the environment of 85° C. and 85% RH, and then, the point, in which the area of dark spots reached to 1% with respect to the whole area, was determined as a service life. In addition, the area of dark spots was calculated as an area ratio when the current of 1 mA/cm² was supplied to each of organic EL devices, and then, the emission image thereof was photographed. The evaluating results are listed in the following Table 3.

TABLE 3

| | | | | | Dark spot 1%- | |
|---|---|---|---|---|---|---|
| | | | | | reaching time | |
| Sample | Barrier | Barrier | Barrier | | Immediately | After |
| No. | layer (1) | layer (2) | layer (3) | Note | evaluation | durability test |
| 109 | Sol-gel-Si | PHPS | | Comparison | 200 | 5 |
| | (130° C.) | | | | | |
| 112 | Sol-gel-Si | PHPS—Al | | Present | 800 | 600 |
| | (130° C.) | | | invention A | | |
| 114 | PHPS—Al | Sol-gel-Si | | Present | 600 | 400 |
| | | (130° C.) | | invention B | | |
| 128 | PHPS | PHPS—Al | | Present | 1500 | 1300 |
| | | | | invention A | | |
| 141 | PHPS | PHPS—Al/B | | Present | 1400 | 1400 |
| | | | | invention A | | |
| 142 | PHPS | HMePS—Al | | Present | 1500 | 1400 |
| | | | | invention A | | |
| 143 | PHPS | PHPS | PHPS—Al | Present | 2000 | 1800 |
| | | | | invention C | | |
| | | | | (First- | | |
| | | | | First-Second) | | |

From the results listed in Table 3, it could be confirmed that the organic EL device using the gas barrier film according to the present invention as a substrate exhibited excellent gas barrier capabilities in the immediate evaluation, and thus, the durability was improved, in which as compared with the case of using the gas barrier film after the durability test as a substrate, the improvement effect on the durability was more excellent.

### Example 3

### Photoelectric Conversion Device (Solar Cell)

<<Production of Photoelectric Conversion Device (Solar Cell)>>

On the barrier layer of the gas barrier film listed in the following Table 4, the indium tin oxide (ITO) transparent conductive film as a first electrode (anode) was deposited to have the thickness of 150 nm (sheet resistance of 12Ω/square), and then, was subjected to the patterning in the width of 10 mm using a general photolithograph method and wet etching to form a first electrode. The first electrode that was patterned was cleaned by an ultrasonic cleaning by ultrapure water and a surfactant and an ultrasonic cleaning by ultrapure water in order; was dried with a nitrogen blow; and finally, was cleaned with ozone cleaning. Next, the isopropanol solution including 2.0% by mass of PEDOT-PSS (CLEVIOS (Registered Trademark) P VP AI 4083, manufactured by Heraeus Holding, conductivity: 1×10⁻³ S/cm) composed of a conductive polymer and polyanion as a hole transport layer was prepared, and then, was applied on a substrate with the dried film thickness of about 30 nm using a blade coater having controlled temperature of 65° C., and then, dried. Then, it was heated for 20 seconds with the hot air of 120° C. to form the hole transport layer on the first electrode. Then, it was put in a glove box, and then, worked in the nitrogen atmosphere.

First, under the nitrogen atmosphere, the device having the hole transport layer was heated at 120° C. for 3 minutes.

Next, an organic photoelectric conversion material composition solution was prepared by mixing 0.8% by mass of the following compound A as a p-type organic semiconductor material and 1.6% by mass of PC60BM (nanom (Registered Trademark) spectra E100H manufactured by Frontier Carbon Corp.) as a n-type organic semiconductor material to o-dichlorobenzene (p-type organic semiconductor material:n-type organic semiconductor material=33:67 (mass ratio)). After completely dissolving it while heating at 100° C. in a hot plate and stirring (for 60 minutes), the solution was applied on a substrate so as to have the dried film thickness of about 170 nm using a blade coater with the controlled temperature of 40° C. and the drying was performed at 120° C. for 2 minutes to form the photoelectric conversion layer on the hole transport layer.

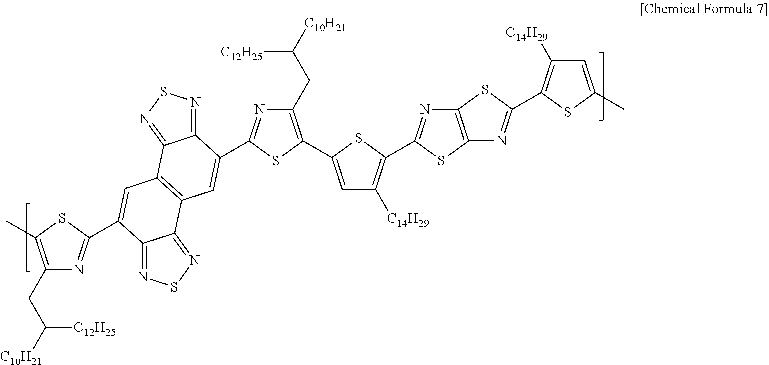

### Compound A

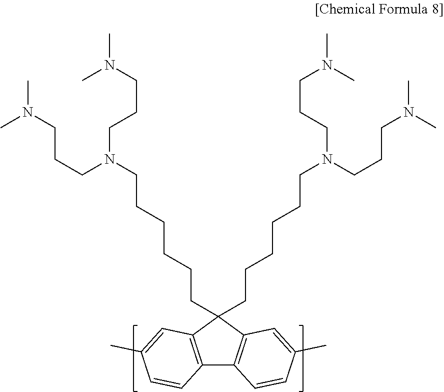

### Compound B

Subsequently, the compound B was dissolved in a mixed solvent of 1-butanol:hexafluoroisopropanol=1:1 with the concentration of 0.02% by mass to form a solution. This solution was applied on a substrate using a blade coater with the controlled temperature of 65° C. so as to have the dried film thickness of about 5 nm. Then, the heating treatment was performed with the hot air of 100° C. fir 2 minutes to form an electron transport layer on the photoelectric conversion layer.

Next, the device with the electron transport layer was installed in a vacuum vapor deposition device. And then, the device was set so as for the shadow mask having the width of 10 mm to be perpendicular to a transparent electrode, the pressure in the vacuum vapor deposition device was reduced to 10⁻³ Pa or less, and then, 100nm of silver was vapor-deposited at the deposition rate of 2 nm/sec to form a second electrode (cathode) on the electron transport layer.

As a sealing member, the member prepared by dry-laminating a polyethylene terephthalate (PET) film (thickness of 12 μm) on an aluminum foil (manufactured by Toyo Aluminium K.K.) having the thickness of 30 μm using an adhesive (2-liquid reaction type urethane-based adhesive) for a dry lamination was used (the thickness of adhesive layer of 1.5 μm), and then, the sealing was performed using a sheet-typed sealing material, TB1655, manufactured by ThreeBond Holdings Co., Ltd. to prepare Samples 301 to 305.

<<Evaluation of Photoelectric Conversion Device (Solar Cell)>>

To the above-produced photoelectric conversion device (solar cell), the durability evaluation was performed according to the following method. In addition, as the gas barrier film used as the substrate of the photoelectric conversion device (solar cell), the films that were immediately evaluated and after durability test were used.

<Measurements of Short-Circuit Current Density, Open Circuit Voltage, Fill Factor, and Photoelectric Conversion Efficiency>

The initial photoelectric conversion efficiency was obtained by evaluating IV properties through irradiating light of the intensity of 100 mW/cm² to the produced organic photoelectric conversion device using a solar simulator (AM1.5 G filter) and overlapping the mask with the effective area of 1 cm² to a light receiving unit.

Then, it was stored under the environment of 85° C. and 85%, and then, the time when the power generation efficiency was reduced by 10% was evaluated as a service life. The evaluation results are listed in the following Table 4.

TABLE 4

| | | | | | Time when power generation | |
|---|---|---|---|---|---|---|
| | | | | | efficiency was reduced by 10% | |
| Sample | Barrier | Barrier | Barrier | | Immediate | After |
| No. | layer (1) | layer (2) | layer (3) | Note | evaluation | durability test |
| 109 | Sol-gel | PHPS | | Comparison | 500 | 100 |
| 112 | Sol-gel | PHPS—Al | | Present | 2000 | 1800 |
| | | | | invention A | | |
| 128 | PHPS single | PHPS—Al | | Present | 3200 | 3000 |
| | layer | | | invention A | | |
| 130 | PHPS—Al | PHPS single | | Present | 2000 | 1800 |
| | | layer | | invention B | | |
| 141 | PHPS single | PHPS—Al/B | | Present | 2500 | 2400 |
| | layer | | | invention A | | |

From the results listed in Table 4, it could be confirmed that the photoelectric conversion device (solar cell) using the gas barrier film according to the present invention as a substrate exhibited excellent gas barrier capabilities in an immediate evaluation, and thus, the durability was improved, in which as compared with the case of using the gas barrier film after the durability test as a substrate, the improvement effect on the durability was more excellent.

The present application is based on the Japanese Patent Application No. 2013-112138 filed on May 28, 2013, the disclosure content thereof is incorporated by reference as a whole.

1. A gas barrier film comprising:
a substrate;
a first barrier layer that is arranged on at least one surface of the substrate, has a film density of 1.5 to 2.1 g/cm³, and includes an inorganic compound; and
a second barrier layer that is formed on the surface of the substrate on the same side where the first barrier layer is formed and includes silicon atoms, oxygen atoms, and at least one added element selected from the group consisting of elements of Groups 2-14 of the long form of the periodic table (excluding silicon and carbon), the abundance ratio of oxygen atoms to silicon atoms (O/Si) being 1.4 to 2.2, and the abundance ratio of nitrogen atoms to silicon atoms (N/Si) being 0 to 0.4.

2. The gas barrier film according to claim 1,
wherein the added element is at least one type selected from the group consisting of boron (B), magnesium (Mg), aluminum (Al), calcium (Ca), titanium (Ti), zinc (Zn), gallium (Ga), germanium (Ge), zirconium (Zr), and indium (In).

3. The gas barrier film according to claim 2,
wherein the added element is at least one type selected from the group consisting of boron (B), aluminum (Al), gallium (Ga), and indium (In).

4. The gas barrier film according to claim 3,
wherein the added element is aluminum (Al).

5. The gas barrier film according to claim 1, the gas barrier film having a constitution of including the substrate, the first barrier layer, and the second barrier layer in order.

6. The gas barrier film according to claim 1, the gas barrier film having three or more layers of the first barrier layers and the second barrier layers in total, wherein the barrier layer that is the closest layer to the substrate is the first barrier layer and the barrier layer that is the furthermost layer from the substrate is the second barrier layer.

7. A method for producing the gas barrier film according to claim 1, the method comprising forming the first barrier layer by applying a first coating solution including an inorganic compound or a precursor thereof on at least one surface of the substrate to form a first coating film, and performing the conversion treatment of the first coating film.

8. The method for producing the gas barrier film according to claim 7,
wherein the forming of the first barrier layer includes forming the first barrier layer by a sol-gel method using a silicon compound, or by the conversion of polysilazane or polysiloxane.

9. The method for producing the gas barrier film according to claim 8,
wherein the forming of the first barrier layer includes forming the first barrier layer by the conversion of polysilazane.

10. The method for producing the gas barrier film according to claim 7, the method further comprising forming the second barrier layer by applying a coating solution including polysilazane and an added compound including at least one added element selected from the group consisting of elements of Groups 2-14 of the long form of the periodic table (excluding silicon and carbon) on the surface of the substrate on the same side where the first barrier layer is formed to form a second coating film, and performing the conversion treatment of the second coating film.

11. The method for producing the gas barrier film according to claim 10,
wherein the conversion treatment to the second coating film is a vacuum UV ray irradiation treatment.

12. An electronic device having the gas barrier film according to claim 1.
